(19) United States
(12) Patent Application Publication
(10) Pub. No.: US 2023/0245958 A1
(43) Pub. Date: Aug. 3, 2023

(54) SEMICONDUCTOR DEVICE

(71) Applicant: ROHM CO., LTD., Kyoto-shi, Kyoto (JP)

(72) Inventor: Hideo HARA, Kyoto-shi, Kyoto (JP)

(21) Appl. No.: 18/007,208

(22) PCT Filed: Nov. 11, 2021
(86) PCT No.: PCT/JP2021/041481

§ 371 Date: Jan. 27, 2023

(30) Foreign Application Priority Data
Dec. 1, 2020 (JP) 2020-199414

(51) Int. Cl. H01L 23/495; H01L 23/31; H01L 23/00

(52) U.S. Cl. CPC H01L 23/49555; H01L 23/3107; H01L 24/06; H01L 24/48; H01L 2224/0603; H01L 2224/06181; H01L 2224/48247

(57) ABSTRACT

A semiconductor device includes: a first semiconductor element to switch between an electrical communication state and a blocked state in accordance with a first driving signal; a first control element to generate the first driving signal based on a first input signal; a second semiconductor element to switch between an electrical communication state and a blocked state in accordance with a second driving signal; and a second control element to generate the second driving signal based on a second input signal. The second input signal is input to the first control element, and thus the first control element determines whether or not the second semiconductor element is in the electrical communication state based on the second input signal. When the second semiconductor element is in the electrical communication state, the first control element delays switching of the first semiconductor element from the blocked state to the electrical communication state.

### TECHNICAL FIELD

The present disclosure relates to a semiconductor device.

### BACKGROUND ART

A semiconductor device called an IPM (Intelligent Power Module) is one of various kinds of semiconductor devices. Such a semiconductor device includes a plurality of semiconductor elements, a plurality of control elements, and a lead frame (see Patent Document 1). The plurality of semiconductor elements are power semiconductor elements for controlling electric power. The plurality of semiconductor elements include a high-voltage semiconductor element and a low-voltage semiconductor element. The high-voltage semiconductor element and the low-voltage semiconductor element are connected to each other in series and form an upper arm and a lower arm. The plurality of control elements respectively control the driving of the plurality of semiconductor elements. The plurality of control elements include a HVIC (High-Voltage IC) for controlling the high-voltage semiconductor element and a LVIC (Low-Voltage IC) for controlling the low-voltage semiconductor element. The lead frame supports the plurality of semiconductor elements and the plurality of control elements, and serves as an electrical communication path for these elements.

### PRIOR ART DOCUMENTS

Patent Document
Patent Document 1: JP-2020-4893A

### SUMMARY OF THE INVENTION

### Problem to be Solved by the Invention

If the semiconductor elements of the upper and lower arms (the high-voltage semiconductor element and the low-voltage semiconductor element) are simultaneously turned on, a power supply short-circuit (arm short-circuit) will occur, and thus a large electric current will flow into the semiconductor elements. Such an arm short-circuit causes breakage of the semiconductor elements.

In light of the above-mentioned circumstances, an object of the present disclosure is to provide a semiconductor device capable of suppressing an arm short-circuit caused by simultaneous turning-on of the upper and lower arms.

### Means for Solving the Problem

A semiconductor device provided by the present disclosure includes: a first semiconductor element configured to receive a first driving signal inputted thereto and to switch between an electrical communication state and a blocked state in accordance with the first driving signal; a first control element configured to receive a first input signal inputted thereto and to generate a first driving signal based on the first input signal and outputs the first driving signal to the first semiconductor element; a second semiconductor element configured to receive a second driving signal inputted thereto and to switch between an electrical communication state and a blocked state in accordance with the second driving signal; and a second control element configured to receive a second input signal inputted thereto and to generate a second driving signal based on the second input signal and outputs the second driving signal to the second semiconductor element. The first control element is configured to receive the second input signal inputted thereto, and when determining, based on the second input signal, that the second semiconductor element is in the electrical communication state, the first control element delays switching of the first semiconductor element from the blocked state to the electrical communication state.

### Advantages of the Invention

With the above-mentioned configuration, it is possible to suppress an arm short-circuit caused by simultaneous turning-on of the upper and lower arms.

### BRIEF DESCRIPTION OF DRAWINGS

FIG. 1 is a perspective view showing a semiconductor device according to a first embodiment.

FIG. 2 shows the perspective view of FIG. 1 in which a sealing member is indicated by imaginary lines (two-dot dash lines).

FIG. 3 is a plan view showing the semiconductor device according to the first embodiment.

FIG. 4 shows the plan view of FIG. 3 in which the sealing member is indicated by imaginary lines (two-dot dash lines).

FIG. 5 is a partially enlarged view in which a portion of FIG. 4 is enlarged.

FIG. 6 is a front view showing the semiconductor device according to the first embodiment.

FIG. 7 is a side view (right side view) showing the semiconductor device according to the first embodiment.

FIG. 8 is a cross-sectional view taken along line VIII-VIII in FIG. 4.

FIG. 9 is a partially enlarged view in which a portion of FIG. 8 is enlarged.

FIG. 10 is a partially enlarged view in which a portion of FIG. 8 is enlarged.

FIG. 11 is a cross-sectional view taken along line XI-XI in FIG. 4.

FIG. 12 is a partially enlarged view in which a portion of FIG. 11 is enlarged.

FIG. 13 is a diagram showing an example of the circuit configuration of the semiconductor device according to the first embodiment.

FIG. 14 is a timing chart showing an operational example of the semiconductor device according to the first embodiment.

FIG. 15 is a timing chart showing an operational example of a conventional semiconductor device.

FIG. 16 is a plan view showing a semiconductor device according to a second embodiment.

FIG. 17 shows the plan view of FIG. 16 in which a sealing member is indicated by imaginary lines (two-dot dash lines).

FIG. 18 is a partially enlarged view in which a portion of FIG. 17 is enlarged.

FIG. 19 is a partially enlarged view in which a portion of FIG. 17 is enlarged.

FIG. 20 is a partially enlarged view in which a portion of FIG. 17 is enlarged.

FIG. 21 is a cross-sectional view taken along line XXI-XXI in FIG. 17.

FIG. 22 is a cross-sectional view taken along line XXII-XXII in FIG. 17.

FIG. 23 is a timing chart showing an operational example of a semiconductor device according to a modified example.

FIG. 24 is a timing chart showing an operational example of a semiconductor device according to a modified example.

FIG. 25 is a plan view showing a semiconductor device according to a modified example in which a sealing member is indicated by imaginary lines (two-dot dash lines).

FIG. 26 is a diagram showing an example of the circuit configuration of the semiconductor device shown in FIG. 25.

FIG. 27 is a timing chart showing an operational example of the semiconductor device shown in FIG. 25.

### MODE FOR CARRYING OUT THE INVENTION

Preferred embodiments of a semiconductor device of the present disclosure will be described below with reference to the drawings. In the following description, the same or similar constituent elements are denoted by the same reference numeral, and redundant descriptions are omitted.

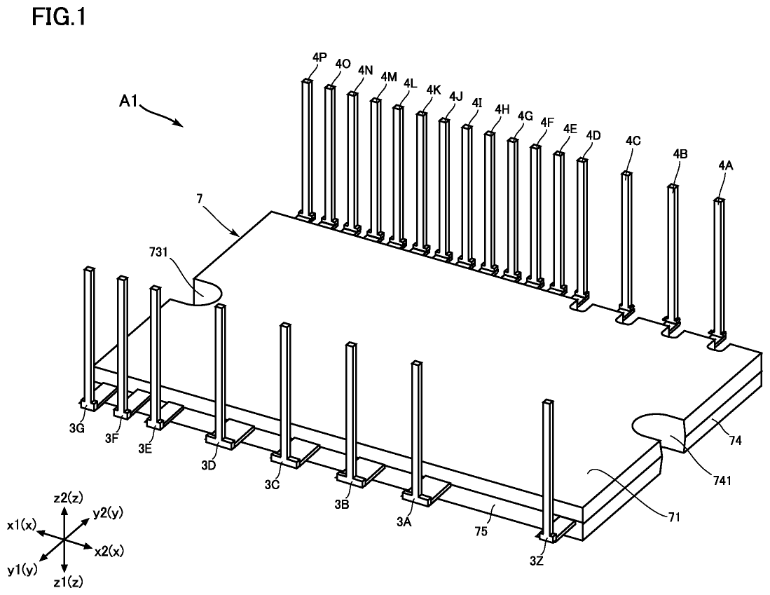

FIGS. 1 to 13 show a semiconductor device A1 according to a first embodiment. As shown in these diagrams, the semiconductor device A1 includes a plurality of semiconductor elements 11 and 12, a plurality of protection elements 13, two control elements 2A and 2B, a plurality of electronic components 29, a plurality of leads 3A to 3G and 3Z, a plurality of leads 4A to 4P, a support substrate 51, a plurality of connection members 6, and a sealing member 7. The plurality of connection members 6 include a plurality of wires 6A to 6K. There is no particular limitation on the application of the semiconductor device A1, and the semiconductor device A1 is configured as, for example, an IPM to be used to control the driving of an inverter motor or the like.

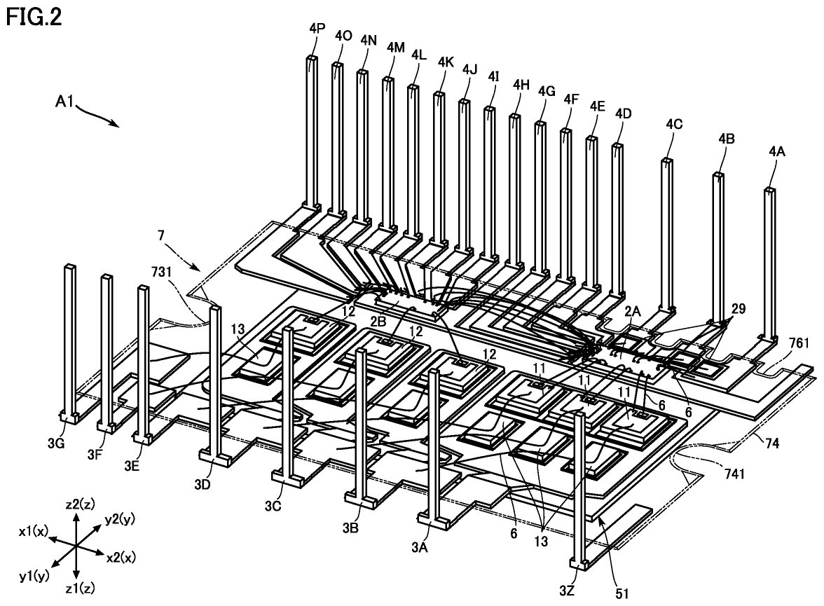

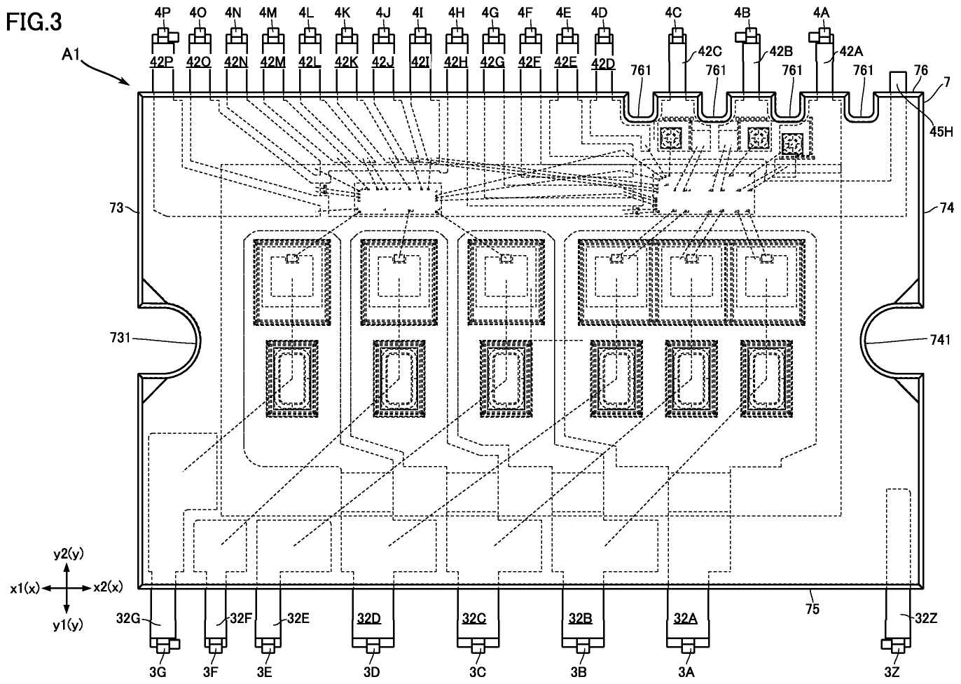

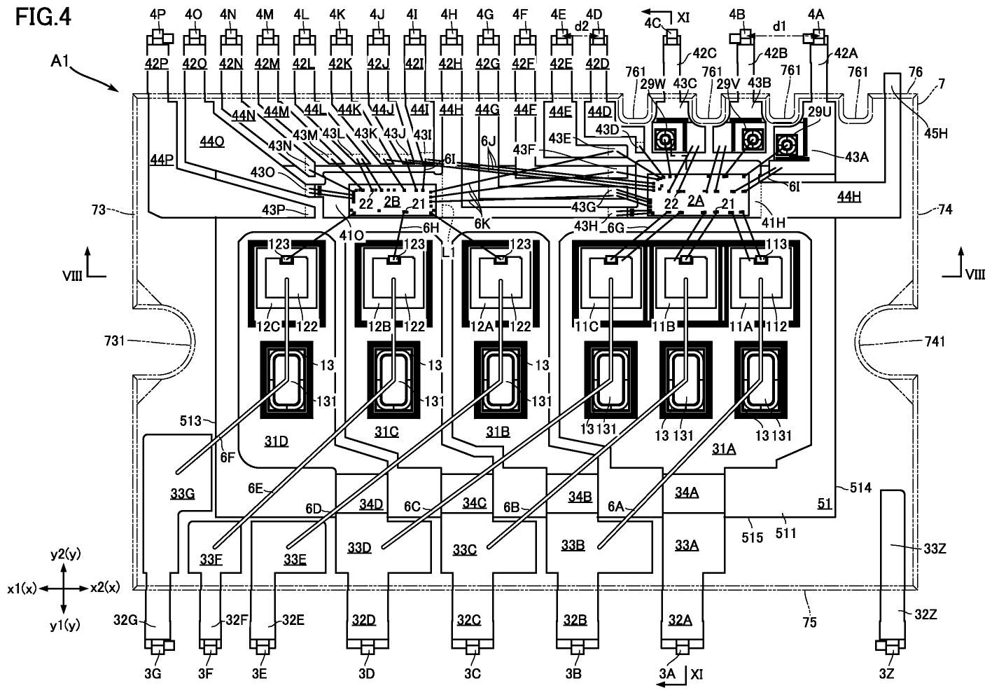

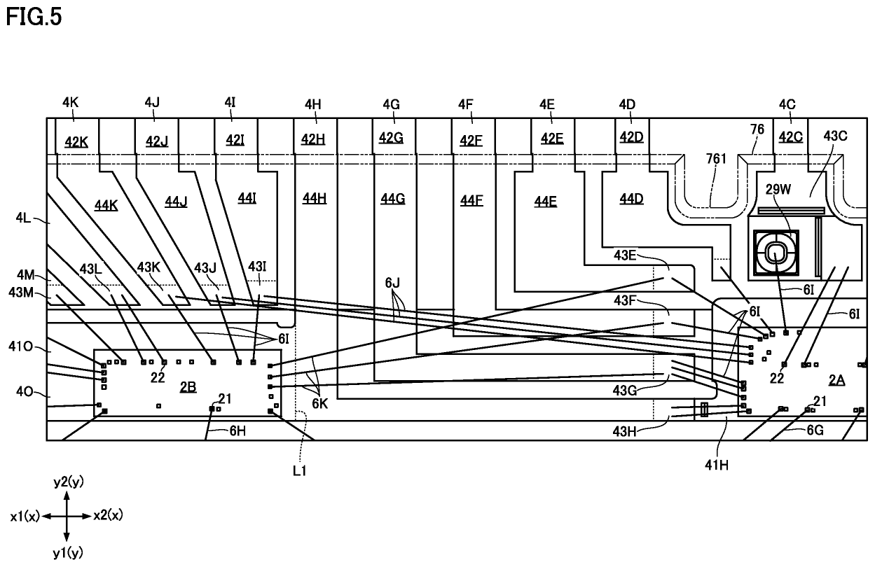

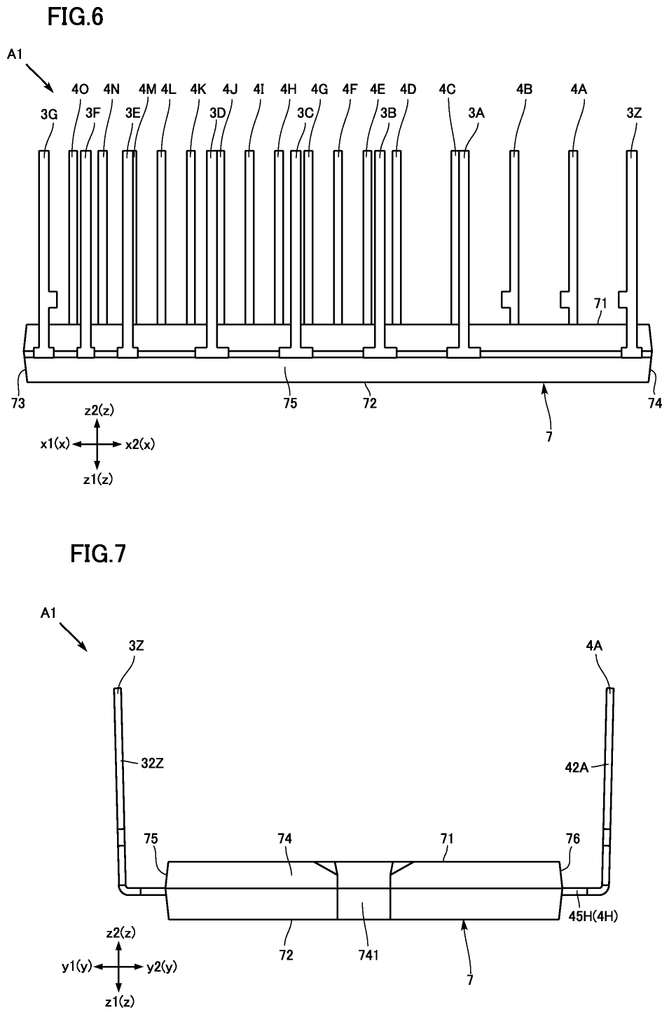

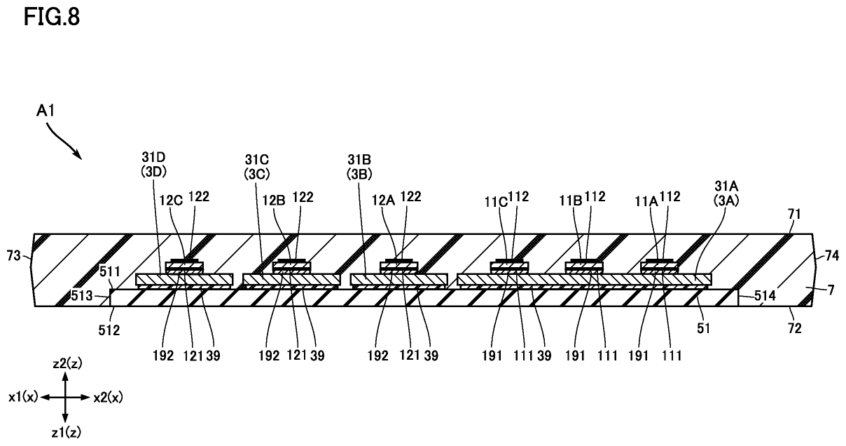

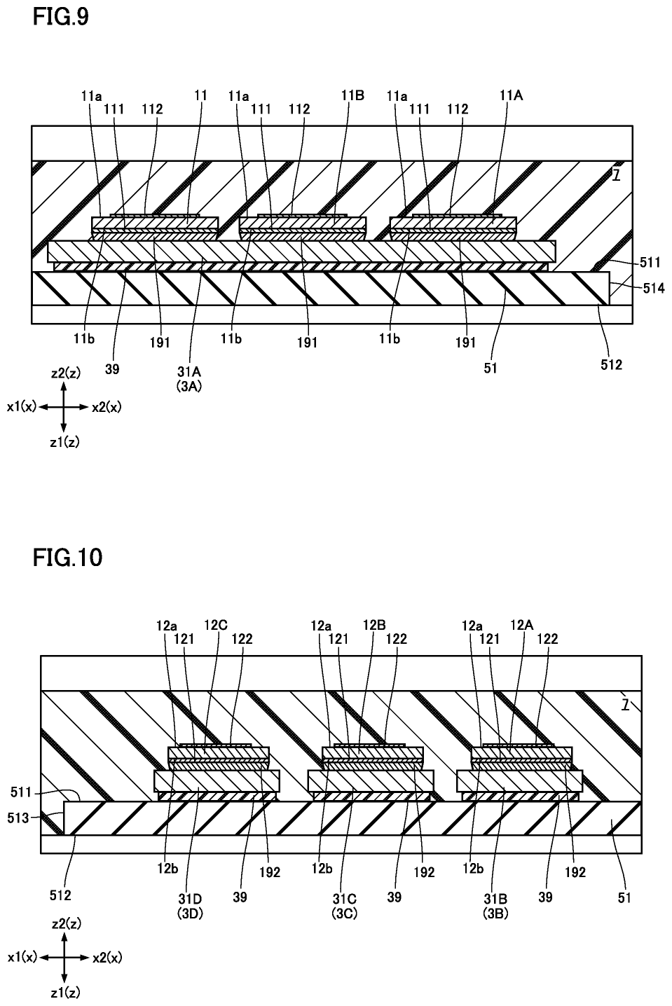

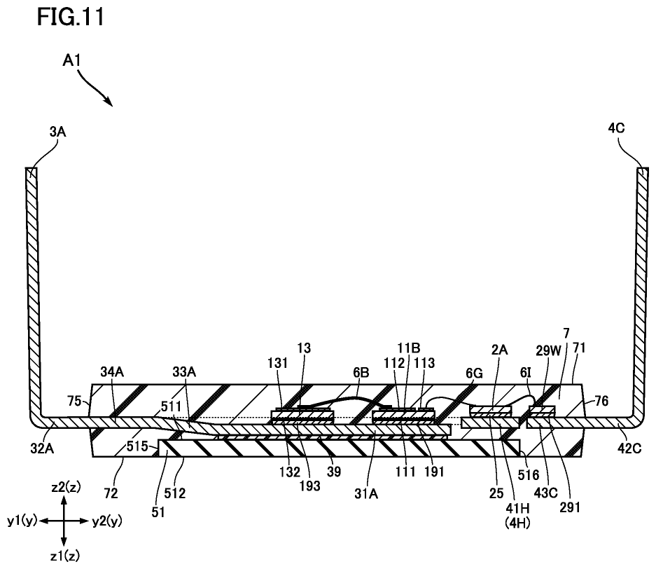

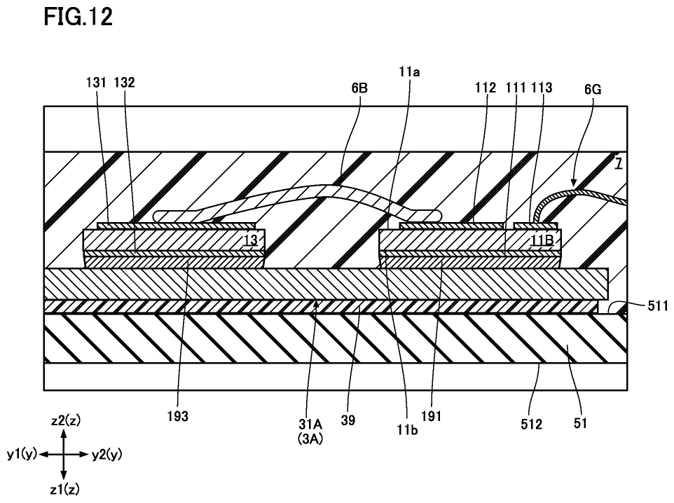

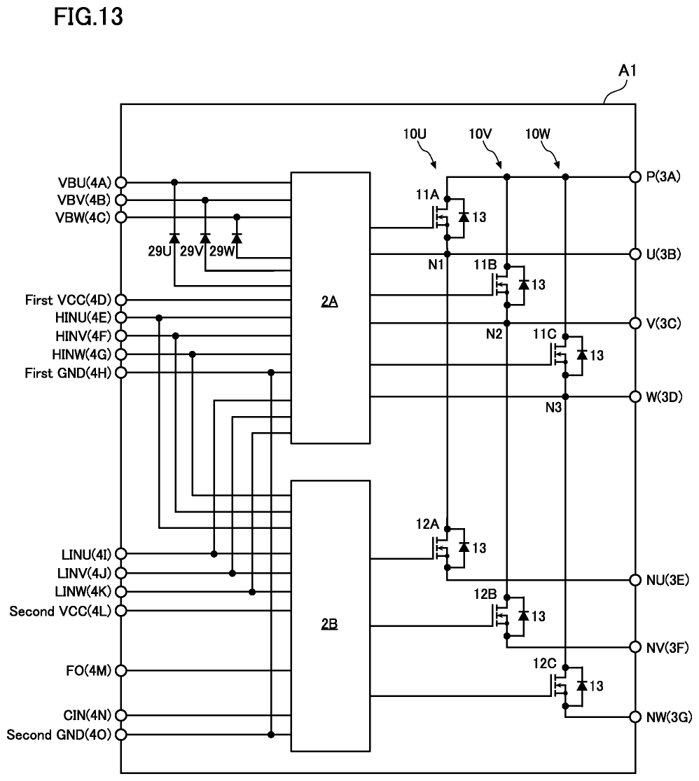

FIG. 1 is a perspective view showing the semiconductor device A1. FIG. 2 shows the perspective view of FIG. 1 in which the sealing member 7 is indicated by imaginary lines (two-dot dash lines). FIG. 3 is a plan view showing the semiconductor device A1. FIG. 4 shows the plan view of FIG. 3 in which the sealing member 7 is indicated by imaginary lines (two-dot dash lines). FIG. 5 is a partially enlarged view in which a portion of FIG. 4 is enlarged. FIG. 6 is a front view showing the semiconductor device A1. FIG. 7 is a side view (right side view) showing the semiconductor device A1. FIG. 8 is a cross-sectional view taken along line VIII-VIII in FIG. 4. FIG. 9 is a partially enlarged view in which a portion of FIG. 8 is enlarged. FIG. 10 is a partially enlarged view in which a portion of FIG. 8 is enlarged. FIG. 11 is a cross-sectional view taken along line XI-XI in FIG. 4. FIG. 12 is a partially enlarged view in which a portion of FIG. 11 is enlarged. FIG. 13 is a diagram showing an example of the circuit configuration of the semiconductor device A1.

In the following description, three directions that are orthogonal to one another, namely the x direction, the y direction, and the z direction, are referred to where appropriate. The z direction corresponds to, for example, the thickness direction of the semiconductor device A1.

The plurality of semiconductor elements 11 and 12 are functional elements for allowing the semiconductor device A1 to function as an IPM. The semiconductor elements 11 and 12 are power-system semiconductor elements, and input and output, for example, a three-phase alternating current to be controlled in an IPM. Examples of the semiconductor elements 11 and 12 include IGBTs (Insulated-Gate Bipolar Transistors), bipolar transistors, MOSFETs (Metal-Oxide-Semiconductor Field-effect Transistors), and HEMTs (High Electron Mobility Transistors). The plurality of semiconductor elements 11 and 12 contain a semiconductor material. Examples of the semiconductor material include SiC (silicon carbide), Si (silicon), GaAs (gallium arsenide), and GaN (gallium nitride). In the examples shown in FIGS. 1 to 12, the semiconductor device A1 includes three semiconductor elements 11 and three semiconductor elements 12, but the number of semiconductor elements 11 and the number of semiconductor elements 12 are not limited thereto. In the following description, the three semiconductor elements 11 are referred to as semiconductor elements 11A, 11B, and 11C when they need to be distinguished from one another. Moreover, the plurality of semiconductor elements 12 are referred to as semiconductor elements 12A, 12B, and 12C when they need to be distinguished from one another. The semiconductor elements 11 are examples of “first semiconductor elements”, and the semiconductor elements 12 are examples of “second semiconductor elements”.

As shown in FIGS. 9 and 12, the plurality of semiconductor elements 11 each include an element obverse surface 11a and an element reverse surface 11b. The element obverse surface 11a and the element reverse surface 11b are spaced apart from each other in the z direction. The element obverse surface 11a faces the z2 side, and the element reverse surface 11b faces the z1 side. The element obverse surface 11a and the element reverse surface 11b are flat (or substantially flat). In each semiconductor element 11, the element reverse surface 11b is opposed to the lead 3A.

As shown in FIGS. 4, 9, and 12, the plurality of semiconductor elements 11 each include a first electrode 111, a second electrode 112, and a third electrode 113. As shown in FIG. 12, the first electrode 111 is provided on the element reverse surface 11b, and the second electrode 112 and the third electrode 113 are provided on the element obverse surface 11a. In an example in which the semiconductor elements 11 are MOSFETs or HEMTs, the first electrode 111 serves as a drain electrode, the second electrode 112 serves as a source electrode, and the third electrode 113 serves as a gate electrode. The semiconductor elements 11 each perform a switching operation in accordance with a driving signal (first driving signal) input to the third electrode 113. The switching operation performed by each semiconductor element 11 is an operation for switching between a state in which the first electrode 111 and the second electrode 112 are in electrical communication with each other and a state.in which these electrodes are blocked from each other.

As shown in FIGS. 8, 9, 11, and 12, the plurality of semiconductor elements 11 are each joined to the lead 3A via a conductive joining material 191. Examples of the conductive joining material 191 include a solder, metal paste materials, and sintered metals.

As shown in FIG. 10, the plurality of semiconductor elements 12 each include an element obverse surface 12a and an element reverse surface 12b. The element obverse surface 12a and the element reverse surface 12b are spaced apart from each other in the z direction. The element obverse surface 12a faces the z2 side, and the element reverse surface 12b faces the z1 side. The element obverse surface 12a and the element reverse surface 12b are flat (or substantially flat). In each semiconductor element 12, the element reverse surface 12b is opposed to one of the leads 3B, 3C, and 3D in accordance with the configuration, which will be described in detail later.

As shown in FIGS. 4 and 10, the plurality of semiconductor elements 12 each include a fourth electrode 121, a fifth electrode 122, and a sixth electrode 123. The fourth electrode 121 is provided on the element reverse surface 12b, and the fifth electrode 122 and the sixth electrode 123 are provided on the element obverse surface 12a. In an example in which the semiconductor elements 12 are MOSFETs, the fourth electrode 121 serves as a drain electrode, the fifth electrode 122 serves as a source electrode, and the sixth electrode 123 serves as a gate electrode. The semiconductor elements 12 each perform a switching operation in accordance with a driving signal (second driving signal) input to the sixth electrode 123. The switching operation performed by each semiconductor element 12 is an operation for switching between a state in which the fourth electrode 121 and the fifth electrode 122 are in electrical communication with each other and a state in which these electrodes are blocked from each other.

As shown in FIGS. 8 and 10, the plurality of semiconductor elements 12 are each joined to one of the plurality of leads 3B, 3C, and 3D via a conductive joining material 192. Examples of the conductive joining material 192 include a solder, metal paste materials, and sintered metals.

The plurality of protection elements 13 are, for example, flyback diodes. As shown in FIG. 4, the plurality of semiconductor elements 11 and 12 are each provided with one protection element 13. As is understood from FIGS. 4, 11 and 12, the plurality of protection elements 13 are each joined to one of the leads 3A to 3D to which the partner semiconductor element 11 or 12 is joined, via a conductive joining material 193. Examples of the conductive joining material 193 include a solder, metal paste materials, and sintered metals. A configuration in which the plurality of protection elements 13 are not provided, which is different from that of the semiconductor device A1, may also be employed.

As shown in FIG. 11, the protection elements 13 each include a first electrode 131 and a second electrode 132. The first electrode 131 is formed on the upper surface (the surface facing the z2 side) of each protection element 13, and the second electrode 132 is formed on the lower surface (the surface facing the z1 side) of each protection element 13. In an example in which the protection elements 13 are diodes, the first electrode 131 serves as an anode electrode, and the second electrode 132 serves as a cathode electrode.

Each protection element 13 is connected to the semiconductor element 11 or 12 in antiparallel. The term “antiparallel” indicates a state in which the semiconductor element 11 or 12 and the protection element 13 are connected to each other in parallel such that the direction in which a forward current flowing in the semiconductor element 11 or 12 and the direction in which a forward current flowing in the protection element 13 are opposite to each other. Specifically, as is understood from FIG. 11, the first electrode 131 of each protection element 13 is connected to the second electrode 112 of the semiconductor element 11 or the fifth electrode 122 of the semiconductor element 12, and the second electrode 132 of each protection element 13 is connected to the first electrode 111 of the semiconductor element 11 or the fourth electrode 121 of the semiconductor element 12. Thus, when a reverse voltage is applied to the semiconductor element 11 or 12, a forward current flows in the protection element 13, thereby reducing the reverse voltage applied to the semiconductor element 11 or 12.

The two control elements 2A and 2B are control-system semiconductor elements, such as driver ICs, for controlling the operations of the plurality of semiconductor elements 11 and 12. The control element 2A controls the switching operations of the semiconductor elements 11 by inputting the first driving signal (e.g., gate voltage) to the third electrodes 113 (gate electrodes) of the semiconductor elements 11. The control element 2A generates the first driving signal for allowing the semiconductor elements 11 to operate as upper arms. The control element 2B controls the switching operations of the semiconductor elements 12 by inputting the second driving signal (e.g., gate voltage) to the sixth electrodes 123 (gate electrodes) of the semiconductor elements 12. The control element 2B generates the second driving signal for allowing the semiconductor elements 12 to operate as lower arms. The control element 2A is an example of a “first control element”, and the control element 2B is an example of a “second control element”.

As shown in FIG. 10, the two control elements 2A and 2B are respectively joined to the leads 4H and 4O via a joining material 25. In the semiconductor device A1, no electrodes are formed on the lower surfaces (surfaces facing the z1 side) of the control elements 2A and 2B, and therefore, the joining material 25 may be a conductive material or an insulating material. Note that, if electrodes are formed on the lower surfaces of the control elements 2A and 2B, a conductive material (e.g., a solder, a metal paste material, or a sintered metal) will be used as the joining material 25.

The plurality of electronic components 29 are elements, such as diodes, for assisting the functions of the two control elements 2A and 2B. In the examples shown in FIGS. 2 and 4, the three electronic components 29 are provided, but the number of electronic components 29 is not limited thereto. The three electronic components 29 are referred to as electronic components 29U, 29V, and 29W when they need to be distinguished from one another. As shown in FIG. 4, the plurality of electronic components 29 are respectively joined to the leads 4A, 4B, and 4C. As shown in FIG. 10, the plurality of electronic components 29 are joined thereto via a conductive joining material 291. Examples of the conductive joining material 291 include a solder, metal paste materials, and sintered metals.

The semiconductor device A1 includes at least the lead 4E (leads 4F, 4G) serving as a first lead, the lead 4I (4J, 4K) serving as a second lead, the leads 4H and 4O serving as third leads, the lead 3A serving as a fourth lead, the lead 3B (3C, 3D) serving as a fifth lead, and the lead 3E (3F, 3G) serving as a sixth lead. In this embodiment, the plurality of leads 3A to 3G and 3Z and the plurality of leads 4A to 4P are provided. As shown in FIGS. 2 to 4, the plurality of leads 3A to 3G and 3Z and the plurality of leads 4A to 4P support the plurality of semiconductor elements 11 and 12, the plurality of protection elements 13, the two control elements 2A and 2B, and the plurality of electronic components 29, and form the electrical communication paths thereto. Out of the plurality of leads 3A to 3G and 3Z and the plurality of leads 4A to 4P, the lead 4H and the lead 4O are integrally formed, and the others are spaced apart from one another. An additional line L1 shown in FIGS. 4 and 5 indicates the boundary between the lead 4H and the lead 4O, namely a portion where these leads are integrally connected to each other. Note that the lead 4H and the lead 4O may be considered as one lead. Unlike this example, the lead 4H and the lead 4O may be spaced apart from each other.

The plurality of leads 3A to 3G and 3Z and the plurality of leads 4A to 4P may be formed using different conductive members or a single conductive member. The plurality of leads 3A to 3G and 3Z and the plurality of leads 4A to 4P are made of, for example, Cu or a Cu alloy. Ni, a Ni alloy, a 42 alloy, and the like may also be used as the constituent materials of the plurality of leads 3A to 3G and 3Z and the plurality of leads 4A to 4P instead of Cu or a Cu alloy. Note that the constituent material of the plurality of leads 3A to 3G and 3Z and the constituent material of the leads 4A to 4P may be the same or different.

When the semiconductor device A1 is configured as an IPM, a motor driving current flows in the plurality of leads 3A to 3G, and a control current flows in the plurality of leads 4A to 4P. Accordingly, a voltage applied to the plurality of leads 3A to 3G is higher than a voltage applied to the plurality of leads 4A to 4P, and a higher electric current flows in the plurality of leads 3A to 3G. In this embodiment, as shown in FIG. 4, the plurality of leads 3A to 3G and 3Z, which are high-voltage leads, and the plurality of leads 4A to 4P, which are low-voltage leads, are separately arranged on opposite sides in the y direction.

In accordance with the configuration, which will be described in detail later, the semiconductor elements 11 are mounted on the lead 3A, and the lead 3A is in electrical communication with the first electrodes 111 of the semiconductor elements 11. As shown in FIG. 4, etc., the lead 3A includes a mounting portion 31A, a terminal portion 32A, a pad portion 33A, and a coupling portion 34A.

The mounting portion 31A is covered by the sealing member 7. As shown in FIGS. 4, 11, and 12, the plurality of semiconductor elements 11 and the plurality of protection elements 13 are mounted on the mounting portion 31A. The mounting portion 31A is in electrical communication with the first electrodes 111 of the semiconductor elements 11 via the conductive joining material 191, and is in electrical communication with the second electrodes 132 of the protection elements 13 via the conductive joining material 193. That is, the first electrodes 111 and the second electrodes 132 are in electrical communication with each other via the mounting portion 31A. As shown in FIGS. 8, 9, 11, and 12, the mounting portion 31A is joined to the support substrate 51 via a joining material 39. The joining material 39 may be a conductive material or an insulating material. It is preferable that the joining material 39 has an excellent thermal conductivity.

As shown in FIG. 4, the terminal portion 32A is a portion of the lead 3A that protrudes from the sealing member 7. The terminal portion 32A protrudes toward a side opposite to the leads 4A to 4P with respect to the mounting portion 31A in the y direction. The terminal portion 32A is used to electrically connect the semiconductor device A1 to an external circuit. In the examples shown in the diagrams, the terminal portion 32A is bent upward in the z direction and has an L-shape.

The pad portion 33A and the coupling portion 34A are covered by the sealing member 7. As shown in FIG. 4, the pad portion 33A and the coupling portion 34A are located between the mounting portion 31A and the terminal portion 32A. The pad portion 33A is located on the z2 side with respect to the mounting portion 31A and is connected to the terminal portion 32A. As shown in FIG. 11, the coupling portion 34A is connected to the mounting portion 31A and the pad portion 33A, and is inclined to the y direction.

As shown in FIGS. 3 and 4, the lead 3B, the lead 3C, and the lead 3D are arranged on the x1 side with respect to the lead 3A. The lead 3B, the lead 3C, and the lead 3D are lined up in the x direction. There is no particular limitation on the shapes of the lead 3B, the lead 3C, and the lead 3D, and in the examples shown in the diagrams, the lead 3B, the lead 3C, and the lead 3D have the same shape (or substantially the same shape) and the same size (or substantially the same size).

The semiconductor element 12A is mounted on the lead 3B. In accordance with the configuration, which will be described in detail later, the lead 3B is in electrical communication with the second electrode 112 of the semiconductor element 11A and the fourth electrode 121 of the semiconductor element 12A. As shown in FIG. 4, the lead 3B includes a mounting portion 31B, a terminal portion 32B, a pad portion 33B, and a coupling portion 34B.

The mounting portion 31B is covered by the sealing member 7. As shown in FIG. 4, the semiconductor element 12A and the protection element 13 are mounted on the mounting portion 31B. The mounting portion 31B is in electrical communication with the fourth electrode 121 of the semiconductor element 12A via the conductive joining material 192, and is in electrical communication with the second electrode 132 of the protection element 13 via the conductive joining material 193. That is, the fourth electrode 121 and the second electrode 132 are in electrical communication with each other via the mounting portion 31B.

As shown in FIG. 4, the terminal portion 32B is a portion of the lead 3B that protrudes from the sealing member 7. The terminal portion 32B protrudes toward a side opposite to the leads 4A to 4P with respect to the mounting portion 31B in the y direction. The terminal portion 32B is used to electrically connect the semiconductor device A1 to an external circuit. In the examples shown in the diagrams, the terminal portion 32B is bent upward in the z direction and has an L-shape.

The pad portion 33B and the coupling portion 34B are covered by the sealing member 7. As shown in FIG. 4, the pad portion 33B and the coupling portion 34B are located between the mounting portion 31B and the terminal portion 32B. As in the case of the pad portion 33A, the pad portion 33B is located on the upper side (z2 side) in the z direction with respect to the mounting portion 31B. The pad portion 33B is connected to the terminal portion 32B. The wire 6A is joined to the pad portion 33B. The coupling portion 34B is connected to the mounting portion 31B and the pad portion 33B, and is inclined to the y direction as in the case of the coupling portion 34A.

The semiconductor element 12B is mounted on the lead 3C. In accordance with the configuration, which will be described in detail later, the lead 3C is in electrical communication with the second electrode 112 of the semiconductor element 11B and the fourth electrode 121 of the semiconductor element 12B. As shown in FIG. 4, the lead 3C includes a mounting portion 31C, a terminal portion 32C, a pad portion 33C, and a coupling portion 34C.

The mounting portion 31C is covered by the sealing member 7. As shown in FIG. 4, the semiconductor element 12B and the protection element 13 are mounted on the mounting portion 31C. The mounting portion 31C is in electrical communication with the fourth electrode 121 of the semiconductor element 12B via the conductive joining material 192, and is in electrical communication with the second electrode 132 of the protection element 13 via the conductive joining material 193. That is, the fourth electrode 121 and the second electrode 132 are in electrical communication with each other via the mounting portion 31C.

As shown in FIG. 4, the terminal portion 32C is a portion of the lead 3C that protrudes from the sealing member 7. The terminal portion 32C protrudes toward a side opposite to the leads 4A to 4P with respect to the mounting portion 31C in the y direction. The terminal portion 32C is used to electrically connect the semiconductor device A1 to an external circuit. In the examples shown in the diagrams, the terminal portion 32C is bent upward in the z direction and has an L-shape.

The pad portion 33C and the coupling portion 34C are covered by the sealing member 7. As shown in FIG. 4, the pad portion 33C and the coupling portion 34C are located between the mounting portion 31C and the terminal portion 32C. As in the case of the pad portions 33A and 33B, the pad portion 33C is located on the upper side (z2 side) in the z direction with respect to the mounting portion 31C. The pad portion 33C is connected to the terminal portion 32C. The wire 6B is joined to the pad portion 33C. The coupling portion 34C is connected to the mounting portion 31C and the pad portion 33C, and is inclined to the y direction as in the case of the coupling portions 34A and 34B.

The semiconductor element 12C is mounted on the lead 3D. In accordance with the configuration, which will be described in detail later, the lead 3D is in electrical communication with the second electrode 112 of the semiconductor element 11C and the fourth electrode 121 of the semiconductor element 12C. As shown in FIG. 4, the lead 3D includes a mounting portion 31D, a terminal portion 32D, a pad portion 33D, and a coupling portion 34D.

The mounting portion 31D is covered by the sealing member 7. As shown in FIG. 4, the semiconductor element 12C and the protection element 13 are mounted on the mounting portion 31D. The mounting portion 31D is in electrical communication with the fourth electrode 121 of the semiconductor element 12C via the conductive joining material 192, and is in electrical communication with the second electrode 132 of the protection element 13 via the conductive joining material 193. That is, the fourth electrode 121 and the second electrode 132 are in electrical communication with each other via the mounting portion 31D.

As shown in FIG. 4, the terminal portion 32D is a portion of the lead 3D that protrudes from the sealing member 7. The terminal portion 32D protrudes toward a side opposite to the leads 4A to 4P with respect to the mounting portion 31D in the y direction. The terminal portion 32D is used to electrically connect the semiconductor device A1 to an external circuit. In the examples shown in the diagrams, the terminal portion 32D is bent upward in the z direction and has an L-shape.

The pad portion 33D and the coupling portion 34D are covered by the sealing member 7. As shown in FIG. 4, the pad portion 33D and the coupling portion 34D are located between the mounting portion 31D and the terminal portion 32D. As in the case of the pad portions 33A, 33B, and 33C, the pad portion 33D is located on the upper side (z2 side) in the z direction with respect to the mounting portion 31D. The pad portion 33D is connected to the terminal portion 32D. The wire 6C is joined to the pad portion 33D. The coupling portion 34D is connected to the mounting portion 31D and the pad portion 33D, and is inclined to the y direction as in the case of the coupling portions 34A, 34B, and 34C.

As shown in FIGS. 3 and 4, the lead 3E, the lead 3F, and the lead 3G are arranged on the x1 side with respect to the lead 3D. The lead 3E, the lead 3F, and the lead 3G are lined up in the x direction. None of the plurality of semiconductor elements 11 and 12 and none of the plurality of protection elements 13 are mounted on the lead 3E, the lead 3F, and the lead 3G.

In accordance with the configuration, which will be described in detail later, the lead 3E is in electrical communication with the fifth electrode 122 of the semiconductor element 12A. As shown in FIG. 4, etc., the lead 3E includes a terminal portion 32E and a pad portion 33E. The terminal portion 32E and the pad portion 33E are connected to each other.

The terminal portion 32E is a portion of the lead 3E that protrudes from the sealing member 7. As shown in FIG. 4, the terminal portion 32E protrudes toward a side opposite to the leads 4A to 4P with respect to the pad portion 33E in the y direction. The terminal portion 32E is used to electrically connect the semiconductor device A1 to an external circuit. In the examples shown in the diagrams, the terminal portion 32E is bent upward in the z direction and has an L-shape.

The pad portion 33E is covered by the sealing member 7 and has a rectangular shape in a plan view in the examples shown in the diagrams. As shown in FIG. 4, the pad portion 33E does not overlap the support substrate 51 in a plan view. As in the case of the pad portions 33A to 33D, the pad portion 33E is located on the upper side (z2 side) in the z direction with respect to the mounting portions 31A to 31D. As shown in FIG. 4, the wire 6D is joined to the pad portion 33E, and the pad portion 33E is in electrical communication with the fifth electrode 122 of the semiconductor element 12A via the wire 6D.

In accordance with the configuration, which will be described in detail later, the lead 3F is in electrical communication with the fifth electrode 122 of the semiconductor element 12B. As shown in FIG. 4, etc., the lead 3F includes a terminal portion 32F and a pad portion 33F. The terminal portion 32F and the pad portion 33F are connected to each other.

The terminal portion 32F is a portion of the lead 3F that protrudes from the sealing member 7. As shown in FIG. 4, the terminal portion 32F protrudes toward a side opposite to the leads 4A to 4P with respect to the pad portion 33F in the y direction. The terminal portion 32F is used to electrically connect the semiconductor device A1 to an external circuit. In the examples shown in the diagrams, the terminal portion 32F is bent upward in the z direction and has an L-shape.

The pad portion 33F is covered by the sealing member 7 and has a rectangular shape in a plan view in the examples shown in the diagrams. As shown in FIG. 4, the pad portion 33F does not overlap the support substrate 51 in a plan view. As in the case of the pad portions 33A to 33E, the pad portion 33F is located on the upper side (z2 side) in the z direction with respect to the mounting portions 31A to 31D. As shown in FIG. 4, the wire 6E is joined to the pad portion 33F, and the pad portion 33F is in electrical communication with the fifth electrode 122 of the semiconductor element 12B via the wire 6E.

In accordance with the configuration, which will be described in detail later, the lead 3G is in electrical communication with the fifth electrode 122 of the semiconductor element 12C. As shown in FIG. 4, etc., the lead 3G includes a terminal portion 32G and a pad portion 33G. The terminal portion 32G and the pad portion 33G are connected to each other.

The terminal portion 32G is a portion of the lead 3G that protrudes from the sealing member 7. As shown in FIG. 4, the terminal portion 32G protrudes toward a side opposite to the leads 4A to 4P with respect to the pad portion 33G in the y direction. The terminal portion 32G is used to electrically connect the semiconductor device A1 to an external circuit. In the examples shown in the diagrams, the terminal portion 32G is bent upward in the z direction and has an L-shape.

The pad portion 33G is covered by the sealing member 7. As shown in FIG. 4, the pad portion 33G does not overlap the support substrate 51 in a plan view. As in the case of the pad portions 33A to 33F, the pad portion 33G is located on the upper side (z2 side) in the z direction with respect to the mounting portions 31A to 31D. As shown in FIG. 4, the wire 6F is joined to the pad portion 33G, and the pad portion 33G is in electrical communication with the fifth electrode 122 of the semiconductor element 12C via the wire 6F.

The lead 3Z is arranged on the x2 side with respect to the lead 3A. The lead 3Z is in electrical communication with none of the plurality of semiconductor elements 11 and 12, none of the plurality of protection elements 13, and neither of the two control elements 2A and 2B. As shown in FIG. 4, etc., the lead 3Z includes a terminal portion 32Z and a pad portion 33Z. The terminal portion 32Z and the pad portion 33Z are connected to each other.

The terminal portion 32Z is a portion of the lead 3Z that protrudes from the sealing member 7. As shown in FIG. 4, the terminal portion 32Z protrudes toward a side opposite to the leads 4A to 4P with respect to the pad portion 33Z in the y direction. In the examples shown in the diagrams, the terminal portion 32Z is bent upward in the z direction and has an L-shape.

The pad portion 33Z is covered by the sealing member 7. As shown in FIGS. 3 and 4, the pad portion 33Z does not overlap the support substrate 51 in a plan view. As in the case of the pad portions 33A to 33G, the pad portion 33Z is located on the upper side (z2 side) in the z direction with respect to the mounting portions 31A to 31D.

As shown in FIGS. 3 and 4, the lead 4A, the lead 4B, and the lead 4C are arranged on the x2 side with respect to the lead 4D. The following is a detailed description of the lead 4A, and the lead 4B and the lead 4C also include the similar constituent parts. In this case, reference numerals obtained by changing the letter “A” in the reference numerals for the constituent parts of the lead 4A to “B” or “C” are used for the constituent parts of the lead 4B and the lead 4C.

As shown in FIG. 4, etc., the lead 4A includes a terminal portion 42A and a pad portion 43A. Although the detailed descriptions are omitted as described above, the lead 4B includes a terminal portion 42B and a pad portion 43B, and the lead 4C includes a terminal portion 42C and a pad portion 43C, as shown in FIG. 4, etc.

The terminal portion 42A is a portion of the lead 4A that protrudes from the sealing member 7. As shown in FIG. 4, the terminal portion 42A protrudes toward a side opposite to the leads 3A to 3G and 3Z with respect to the pad portion 43A in the y direction. The terminal portion 42A is used to electrically connect the semiconductor device A1 to an external circuit. In the examples shown in the diagrams, the terminal portion 42A is bent upward in the z direction and has an L-shape.

The pad portion 43A is covered by the sealing member 7. As shown in FIG. 4, the electronic components 29 and the wires 61 are joined to the pad portion 43A. An electronic component 29U is joined to the pad portion 43A, an electronic component 29V is joined to the pad portion 43B, and an electronic component 29W is joined to the pad portion 43C. The shape of the pad portion 43A is not limited to those of the examples shown in the diagrams.

As shown in FIGS. 3 and 4, the plurality of leads 4D to 4G are arranged on the x1 side with respect to the lead 4C. The following is a detailed description of the lead 4D, and the leads 4E, 4F, and 4G also include the similar constituent parts. In this case, reference numerals obtained by changing the letter “D” in the reference numerals for the constituent parts of the lead 4D to “E”, “F”, or “G” are used for the constituent parts of the leads 4E, 4F, and 4G.

As shown in FIG. 4, etc., the lead 4D includes a terminal portion 42D, a pad portion 43D, and a coupling portion 44D. Although the detailed descriptions are omitted as described above, the lead 4E includes a terminal portion 42E, a pad portion 43E, and a coupling portion 44E, the lead 4F includes a terminal portion 42F, a pad portion 43F, and a coupling portion 44F, and the lead 4G includes a terminal portion 42G, a pad portion 43G, and a coupling portion 44G, as shown in FIG. 4, etc. The terminal portion 42E (42F, 42G) is an example of a “first terminal portion”.

The terminal portion 42D is a portion of the lead 4D that protrudes from the sealing member 7. As shown in FIG. 4, the terminal portion 42D protrudes toward a side opposite to the leads 3A to 3G and 3Z with respect to the pad portion 43D in the y direction. The terminal portion 42D is used to electrically connect the semiconductor device A1 to an external circuit. In the examples shown in the diagrams, the terminal portion 42D is bent upward in the z direction and has an L-shape.

The pad portion 43D is covered by the sealing member 7. As shown in FIG. 4, the wires 61 are joined to the pad portion 43D, and the pad portion 43D is in electrical communication with the second electrode 22 of the control element 2A via the wires 61. Moreover, as shown in FIG. 5, the wires 6K are also joined to the pad portions 43E, 43F, and 43G in addition to the wires 61. In this embodiment, the pad portions 43E, 43F, and 43G are examples of a “first conductive portion”.

The coupling portion 44D is covered by the sealing member 7. As shown in FIG. 4, the coupling portion 44D is connected to the terminal portion 42D and the pad portion 43D, and is located therebetween.

The control element 2A is mounted on the lead 4H. As shown in FIG. 4, etc., the lead 4H includes a mounting portion 41H, a terminal portion 42H, a pad portion 43H, a plurality of coupling portions 44H, and a protruding portion 45H.

The mounting portion 41H is covered by the sealing member 7. As shown in FIGS. 4 and 11, the control element 2A is mounted on the mounting portion 41H. As described above, the control element 2A is adhered to the mounting portion 41H using the joining material 25. As shown in FIG. 11, the mounting portion 41H is spaced apart from the support substrate 51 in the z direction.

The terminal portion 42H is a portion of the lead 4H that protrudes from the sealing member 7. As shown in FIG. 4, the terminal portion 42H protrudes toward a side opposite to the leads 3A to 3G and 3Z with respect to the mounting portion 41H in the y direction. The terminal portion 42H is used to electrically connect the semiconductor device A1 to an external circuit. In the examples shown in the diagrams, the terminal portion 42H is bent in the z direction and has an L-shape.

The pad portion 43H is covered by the sealing member 7. The pad portion 43H is adjacent to the mounting portion 41H. As shown in FIG. 4, the wires 61 are joined to the pad portion 43H.

The plurality of coupling portions 44H are covered by the sealing member 7. Some of the plurality of coupling portion 44H are located between and connected to the terminal portion 42H and the pad portion 43H, while others are located between and connected to the mounting portion 41H and the protruding portion 45H.

As shown in FIG. 4, the protruding portion 45H extends toward the y2 side from the coupling portion 44H that is connected to the mounting portion 41H, and protrudes from the sealing member 7.

The control element 2B is mounted on the lead 4O. As shown in FIG. 4, etc., the lead 4O includes a mounting portion 410, a terminal portion 420, a pad portion 430, and a coupling portion 440.

The mounting portion 410 is covered by the sealing member 7. As shown in FIG. 4, the control element 2B is mounted on the mounting portion 410. As described above, the control element 2B is adhered to the mounting portion 410 using the joining material 25. As in the case of the mounting portion 41H, the mounting portion 410 is spaced apart from the support substrate 51 in the z direction (see FIG. 11).

The terminal portion 420 is a portion of the lead 4O that protrudes from the sealing member 7. As shown in FIG. 4, the terminal portion 420 protrudes toward a side opposite to the leads 3A to 3G and 3Z with respect to the mounting portion 410 in the y direction. The terminal portion 420 is used to electrically connect the semiconductor device A1 to an external circuit. In the examples shown in the diagrams, the terminal portion 420 is bent in the z direction and has an L-shape.

The pad portion 430 is covered by the sealing member 7. The pad portion 430 is adjacent to the mounting portion 410. As shown in FIG. 4, the wires 61 are joined to the pad portion 430.

The coupling portion 440 is covered by the sealing member 7. The coupling portion 440 is located between and connected to the terminal portion 420 and the pad portion 430.

As shown in FIGS. 3 and 4, the plurality of leads 4I to 4N and 4P are arranged on the x1 side with respect to the lead 4H. The following is a detailed description of the lead 4I, and the leads 4J, 4K, 4L, 4M, 4N, and 4P also include the similar constituent parts. In this case, reference numerals obtained by changing the letter “I” in the reference numerals for the constituent parts of the lead 4I to “J”, “K”, “L”, “M”, “N”, or “P” are used for the constituent parts of the leads 4J, 4K, 4L, 4M, 4N and 4P.

As shown in FIGS. 4 and 5, etc., the lead 4I includes a terminal portion 421, a pad portion 431, and a coupling portion 441. Although the detailed descriptions are omitted as described above, the lead 4J includes a terminal portion 42J, a pad portion 43J, and a coupling portion 44J, the lead 4K includes a terminal portion 42K, a pad portion 43K, and a coupling portion 44K, the lead 4L includes a terminal portion 42L, a pad portion 43L, and a coupling portion 44L, the lead 4M includes a terminal portion 42M, a pad portion 43M, and a coupling portion 44M, the lead 4N includes a terminal portion 42N, a pad portion 43N, and a coupling portion 44N, and the lead 4P includes a terminal portion 42P, a pad portion 43P, and a coupling portion 44P, as shown in FIGS. 4 and 5, etc. The terminal portion 421 (42J, 42K) is an example of a “second terminal portion”.

The terminal portion 421 is a portion of the lead 4I that protrudes from the sealing member 7. As shown in FIGS. 4 and 5, the terminal portion 421 protrudes toward a side opposite to the leads 3A to 3G and 3Z with respect to the pad portion 431 in the y direction. The terminal portion 421 is used to electrically connect the semiconductor device A1 to an external circuit. In the examples shown in the diagrams, the terminal portion 421 is bent in the z direction and has an L-shape. The terminal portions 421 to 42N of the plurality of leads 4I to 4N are located between the terminal portion 42H of the lead 4H and the terminal portion 420 of the lead 4O in the x direction, and the terminal portion 42P of the lead 4P is located on the x1 side with respect to the terminal portion 420.

The pad portion 431 is covered by the sealing member 7. As shown in FIGS. 4 and 5, the wires 61 are joined to the pad portion 431, and the pad portion 431 is in electrical communication with the second electrode 22 of the control element 2B via the wires 61. However, in the examples shown in FIGS. 4 and 5, the wires 61 are not joined to the pad portion 43P. Moreover, as shown in FIG. 5, the wires 6J are also joined to the pad portions 431, 43J, and 43K in addition to the wires 61. In this embodiment, the pad portions 431, 43J, and 43K are examples of a “second conductive portion”.

The coupling portion 441 is covered by the sealing member 7. As shown in FIG. 4, the coupling portion 441 is connected to the terminal portion 421 and the pad portion 431, and is located therebetween.

In the examples shown in the diagrams, the plurality of terminal portions 42A to 42C are lined up in the x direction with first pitches d1 (see FIG. 4). Moreover, the plurality of terminal portions 42D to 42P are lined up in the x direction with second pitches d2 (see FIG. 4). The first pitch d1 is larger than the second pitch d2. The distance between the terminal portion 42C and the terminal portion 42D in the x direction is the first pitch d1.

The support substrate 51 supports the plurality of leads 3A to 3D, and, for example, transfers heat generated by the plurality of semiconductor elements 11 and 12 and the plurality of protection elements 13 to the outside of the semiconductor device A1 via the leads 3A to 3D. The support substrate 51 has a plate shape with a rectangular shape in a plan view. The support substrate 51 is made of an insulating material, and examples of the insulating material include ceramics such as alumina (Al₂O₃), silicon nitride (SiN), aluminum nitride (AlN), and zirconia-containing alumina. Note that the support substrate 51 is preferably made of ceramics from the viewpoint of the strength, the heat transfer coefficient, and the insulating properties, but the material thereof is not limited to ceramics, and various materials (e.g., an epoxy resin, silicone, and the like) are employed. Moreover, it is preferable that the heat transfer coefficient of the material of the support substrate 51 is higher than that of the sealing member 7.

As shown in FIGS. 4 and 8 to 12, the support substrate 51 has a first surface 511, a second surface 512, a third surface 513, a fourth surface 514, a fifth surface 515, and a sixth surface 516. As shown in FIGS. 8 to 12, the first surface 511 and the second surface 512 are spaced apart in the z direction. The first surface 511 faces the z2 side, and the second surface 512 faces the z1 side. As shown in FIG. 8, the mounting portions 31A, 31B, 31C, and 31D are joined to the first surface 511 via the joining material 39. As shown in FIGS. 8 to 12, the second surface 512 is exposed from the sealing member 7. The third surface 513, the fourth surface 514, the fifth surface 515, and the sixth surface 516 are located between and connected to the first surface 511 and the second surface 512 in the z direction. As shown in FIGS. 4 and 8, the third surface 513 and the fourth surface 514 are spaced apart in the x direction. The third surface 513 faces the x1 side, and the fourth surface 514 faces the x2 side. As shown in FIGS. 4 and 11, the fifth surface 515 and the sixth surface 516 are spaced apart in the y direction. The fifth surface 515 faces the y1 side, and the sixth surface 516 faces the y2 side. In the examples shown in the diagrams, the first surface 511, the second surface 512, the third surface 513, the fourth surface 514, the fifth surface 515, and the sixth surface 516 are flat.

The plurality of connection members 6 each enable electrical communication between two portions that are spaced apart from each other. As is understood from FIGS. 2, 4, and 5, the plurality of connection members 6 include the plurality of wires 6A to 6K. The wires 6A to 6K (connection members 6) are bonding wires. Note that plate-shaped conductive lead members may also be used as the connection members 6 instead of the wires 6A to 6K.

As shown in FIG. 4, the wire 6A is joined to the second electrode 112 of the semiconductor element 11A and the pad portion 33B of the lead 3B. Moreover, a portion of the wire 6A between the above-mentioned joined portions is joined to the first electrode 131 of the protection element 13 (rightmost protection element 13 in FIG. 4). Thus, the second electrode 112 of the semiconductor element 11A is in electrical communication with the lead 3B via the wire 6A in FIG. 4, and is in electrical communication with the first electrode 131 of the protection element 13 located at the rightmost position in FIG. 4. Since the lead 3B is in electrical communication with the fourth electrode 121 of the semiconductor element 12A, the fourth electrode 121 of the semiconductor element 12A and the second electrode 112 of the semiconductor element 11A are in electrical communication with each other via the lead 3B and the wire 6A.

As shown in FIG. 4, the wire 6B is joined to the second electrode 112 of the semiconductor element 11B and the pad portion 33C of the lead 3C. Moreover, a portion of the wire 6B between the above-mentioned joined portions is joined to the first electrode 131 of the protection element 13 (second protection element 13 from the right in FIG. 4). Thus, the second electrode 112 of the semiconductor element 11B is in electrical communication with the lead 3C via the wire 6B, and is in electrical communication with the first electrode 131 of the second protection element 13 from the right in FIG. 4. Since the lead 3C is in electrical communication with the fourth electrode 121 of the semiconductor element 12B, the fourth electrode 121 of the semiconductor element 12B and the second electrode 112 of the semiconductor element 11B are in electrical communication with each other via the lead 3C and the wire 6B.

As shown in FIG. 4, the wire 6C is joined to the second electrode 112 of the semiconductor element 11C and the pad portion 33D of the lead 3D. Moreover, a portion of the wire 6C between the above-mentioned joined portions is joined to the first electrode 131 of the protection element 13 (third protection element 13 from the right in FIG. 4). Thus, the second electrode 112 of the semiconductor element 11C is in electrical communication with the lead 3D via the wire 6C, and is in electrical communication with the first electrode 131 of the third protection element 13 from the right in FIG. 4. Since the lead 3D is in electrical communication with the fourth electrode 121 of the semiconductor element 12C, the fourth electrode 121 of the semiconductor element 12C and the second electrode 112 of the semiconductor element 11C are in electrical communication with each other via the lead 3D and the wire 6C.

As shown in FIG. 4, the wire 6D is joined to the fifth electrode 122 of the semiconductor element 12A and the pad portion 33E of the lead 3E. Moreover, a portion of the wire 6D between the above-mentioned joined portions is joined to the first electrode 131 of the protection element 13 mounted on the lead 3B. Thus, the fifth electrode 122 of the semiconductor element 12A is in electrical communication with the lead 3E via the wire 6D, and is in electrical communication with the first electrode 131 of the protection element 13 mounted on the lead 3B.

As shown in FIG. 4, the wire 6E is joined to the fifth electrode 122 of the semiconductor element 12B and the pad portion 33F of the lead 3F. Moreover, a portion of the wire 6E between the above-mentioned joined portions is joined to the first electrode 131 of the protection element 13 mounted on the lead 3C. Thus, the fifth electrode 122 of the semiconductor element 12B is in electrical communication with the lead 3F via the wire 6E, and is in electrical communication with the first electrode 131 of the protection element 13 mounted on the lead 3C.

As shown in FIG. 4, the wire 6F is joined to the fifth electrode 122 of the semiconductor element 12C and the pad portion 33G of the lead 3G. Moreover, a portion of the wire 6F between the above-mentioned joined portions is joined to the first electrode 131 of the protection element 13 mounted on the lead 3D. Thus, the fifth electrode 122 of the semiconductor element 12C is in electrical communication with the lead 3G via the wire 6F, and is in electrical communication with the first electrode 131 of the protection element 13 mounted on the lead 3D.

As shown in FIG. 4, the plurality of wires 6G are each connected to the second electrode 112 or third electrode 113 of the semiconductor element 11 and a first electrode 21 of the control element 2A. Accordingly, each wire 6G enables electrical communication between the second electrode 112 and the first electrode 21 or between the third electrode 113 and the first electrode 21. The above-mentioned first driving signal flows in the wires 6A that are each connected to the third electrode 113 of the semiconductor element 11 and the first electrode 21 of the control element 2A.

As shown in FIG. 4, the plurality of wires 6H are each connected to the sixth electrode 123 of the semiconductor element 12 and the first electrode 21 of the control element 2B. Accordingly, each wire 6H enables electrical communication between the sixth electrode 123 and the first electrode 21. The above-mentioned second driving signal flows in the wires 6H.

As shown in FIG. 4, the plurality of wires 61 are each connected to one of the second electrodes 22 of the control elements 2A and 2B, and one of the plurality of electronic components 29 or one of the pad portions 43A to 43P of the plurality of leads 4A to 4P. Accordingly, each wire 61 enables electrical communication between the control element 2A or 2B and the one of the leads 4A to 4P.

As shown in FIGS. 4 and 5, the plurality of wires 6K are each connected to the second electrode 22 of the control element 2B and one of the pad portions 43E, 43F, and 43G of the leads 4E, 4F, and 4G. Accordingly, each wire 6K enables electrical communication between the control element 2B and the one of the leads 4E, 4F, and 4G. The wires 6K are examples of a “first connection member”.

As shown in FIGS. 4 and 5, the plurality of wires 6J are each connected to the second electrode 22 of the control element 2A and one of the pad portions 431, 43J, and 43K of the leads 4I, 4J, and 4K. Accordingly, each wire 6J enables electrical communication between the control element 2A and the one of the leads 4I, 4J, and 4K. The wires 6J are examples of a “second connection member”.

Regarding the plurality of connection members 6, the diameters of the wires 6A to 6F are larger than those of the wires 6G to 6K. The reason for this is that, when the semiconductor device A1 is configured as an IPM, a voltage applied to the plurality of leads 3A to 3G is higher than a voltage applied to the plurality of leads 4A to 4F, and a higher electric current flows in the plurality of leads 3A to 3G. The wires 6A to 6F are made of, for example, Al or an Al alloy. Au or an Au alloy, or Cu or a Cu alloy may also be used as the constituent materials of the wires 6A to 6F instead of Al or an Al alloy. The wires 6G to 6K are made of, for example, Au or an Au alloy. Al or an Al alloy, or Cu or a Cu alloy may also be used as the constituent materials of the wires 6G to 6K instead of Au or an Au alloy.

As shown in FIGS. 1, 3, 4, and 6 to 12, the sealing member 7 covers the plurality of semiconductor elements 11 and 12, the plurality of protection elements 13, the two control elements 2A and 2B, the plurality of electronic components 29, a portion of each of the plurality of leads 3A to 3G and 3Z, a portion of each of the plurality of leads 4A to 4P, a portion of the support substrate 51, and the plurality of connection members 6. The sealing member 7 is made of, for example, a black epoxy resin. The sealing member 7 has a resin obverse surface 71, a resin reverse surface 72, and a plurality of resin side surfaces 73 to 76.

As shown in FIGS. 6 to 8 and 10, the resin obverse surface 71 and the resin reverse surface 72 are spaced apart from each other in the z direction. The resin obverse surface 71 faces the z2 side, and the resin reverse surface 72 faces the z1 side. The resin obverse surface 71 and the resin reverse surface 72 are flat (or substantially flat). The resin side surfaces 73 to 76 are located between and connected to the resin obverse surface 71 and the resin reverse surface 72 in the z direction. As shown in FIGS. 3, 4 and 8, the resin side surface 73 and the resin side surface 74 are spaced apart from each other in the x direction. The resin side surface 73 faces the x1 side, and the resin side surface 74 faces the x2 side. As shown in FIGS. 3, 4, and 11, the resin side surface 75 and the resin side surface 76 are spaced apart from each other in the y direction. The resin side surface 75 faces the y1 side, and the resin side surface 76 faces the y2 side. As shown in FIGS. 3 and 4, etc., the resin side surface 73 is provided with a recessed portion 731 that is recessed in the x direction. The resin side surface 74 is provided with a recessed portion 741 that is recessed in the x direction. The recessed portion 731 and the recessed portion 741 are used to, for example, fix the semiconductor device A1 while installing it. The resin side surface 76 is provided with a plurality of recessed portions 761 that are each recessed in the y direction.

In the semiconductor device A1, a first DC voltage applied to the terminal portion 32A (lead 3A) and the terminal portion 32E (lead 3E) is converted to a first AC voltage by the switching operations of the semiconductor element 11A and the semiconductor element 12A. The frequency of the first AC voltage depends on the switching frequencies of the semiconductor element 11A and the semiconductor element 12A. The first AC voltage is output from the terminal portion 32B (lead 3B). A second DC voltage applied to the terminal portion 32A (lead 3A) and the terminal portion 32F (lead 3F) is converted to a second AC voltage by the switching operations of the semiconductor element 11B and the semiconductor element 12B. The frequency of the second AC voltage depends on the switching frequencies of the semiconductor element 11B and the semiconductor element 12B. The second AC voltage is output from the terminal portion 32C (lead 3C). A third DC voltage applied to the terminal portion 32A (lead 3A) and the terminal portion 32G (lead 3G) is converted to a third AC voltage by the switching operations of the semiconductor element 11C and the semiconductor element 12C. The frequency of the third AC voltage depends on the switching frequencies of the semiconductor element 11C and the semiconductor element 12C. The third AC voltage is output from the terminal portion 32D (lead 3D).

Next, the circuit configuration of the semiconductor device A1 will be described with reference to FIG. 13. In FIG. 13, the semiconductor elements 11 and 12 are MOSFETs.

As shown in FIG. 13, the semiconductor device A1 has a configuration in which three switching arms 10U, 10V, and 10W are connected to one another in parallel. The switching arm 10U includes the semiconductor elements 11A and 12A, the switching arm 10V includes the semiconductor elements 11B and 12B, and the switching arm 10W includes the semiconductor elements 11C and 12C.

The drains (first electrodes 111) of the semiconductor elements 11A to 11C are connected to one another, and are connected to a P terminal (lead 3A). The source (second electrode 112) of the semiconductor element 11A is connected to the drain (fourth electrode 121) of the semiconductor element 12A, the source (second electrode 112) of the semiconductor element 11B is connected to the drain (fourth electrode 121) of the semiconductor element 12B, and the source (second electrode 112) of the semiconductor element 11C is connected to the drain (fourth electrode 121) of the semiconductor element 12C. A node N1 located between the source of the semiconductor element 11A and the drain of the semiconductor element 12A is connected to a U terminal (lead 3B). A node N2 located between the source of the semiconductor element 11B and the drain of the semiconductor element 12B is connected to a V terminal (lead 3C). A node N3 located between the source of the semiconductor element 11C and the drain of the semiconductor element 12C is connected to a W terminal (lead 3D). The source (fifth electrode 122) of the semiconductor element 12A is connected to an NU terminal (lead 3E), the source (fifth electrode 122) of the semiconductor element 12B is connected to an NV terminal (lead 3F), and the source (fifth electrode 122) of the semiconductor element 12C is connected to an NW terminal (lead 3G).

The level of voltage applied to the U terminal (lead 3B), the V terminal (lead 3C), and the W terminal (lead 3D) is, for example, about 0 V to 650 V. On the other hand, the level of voltage applied to the NU terminal (lead 3E), the NV terminal (lead 3F), and the NW terminal (lead 3G) is, for example, about 0 V, and is lower than the level of voltage applied to the U terminal (lead 3B), the V terminal (lead 3C), and the W terminal (lead 3D). The semiconductor elements 11A to 11C form a high-potential transistor for a three-phase inverter circuit, and the semiconductor elements 12A to 12C form a low-potential transistor for a three-phase inverter circuit.

The gates (third electrodes 113) of the semiconductor elements 11A to 11C are connected to the control element 2A, and the sources (second electrodes 112) of the semiconductor elements 11A to 11C are connected to the control element 2A. The gates (sixth electrodes 123) of the semiconductor elements 12A to 12C are connected to the control element 2B.

An external gate control circuit (not illustrated) is connected to an HINU terminal (lead 4E), an HINV terminal (lead 4F), and an HINW terminal (lead 4G), and a first input signal is input thereto from the gate control circuit. The external gate control circuit is connected to an LINU terminal (lead 4I), an LINV terminal (lead 4J), and an LINW terminal (lead 4K), and a second input signal is input thereto from the gate control circuit.

The control element 2A is electrically connected to a VBU terminal (lead 4A), a VBV terminal (lead 4B), a VBW terminal (lead 4C), a first VCC terminal (lead 4D), the HINU terminal (lead 4E), the HINV terminal (lead 4F), the HINW terminal (lead 4G), and a first GND terminal (lead 4H). Also, the control element 2A is electrically connected to the HINU terminal (lead 4E), the HINV terminal (lead 4F), and the HINW terminal (lead 4G). The first VCC terminal is a terminal for supplying a power source voltage VCC to the control element 2A. The first input signal is input to the control element 2A from the HINU terminal, the HINV terminal, and the HINW terminal, and the second input signal is input thereto from the LINU terminal, the LINV terminal, and the LINW terminal. The control element 2A generates the first driving signal (e.g., gate voltage) for driving the semiconductor elements 11A to 11C based on the first input signal and the second input signal that have been input thereto. Then, the generated first driving signal is input to the gates (third electrodes 113) of the semiconductor elements 11A to 11C. The first GND terminal (lead 4H) and a second GND terminal (lead 4O) are connected to each other inside the semiconductor device A1, and have the same electrical potential.

The control element 2B is electrically connected to the LINU terminal (lead 4I), the LINV terminal (lead 4J), the LINW terminal (lead 4K), a second VCC terminal (lead 4L), an FO terminal (lead 4M), a CIN terminal (lead 4N), and the second GND terminal (lead 4O). Also, the control element 2B is electrically connected to the HINV terminal (lead 4F), the HINW terminal (lead 4G), and the first GND terminal (lead 4H). The second VCC terminal is a terminal for supplying the power source voltage VCC to the control element 2B. The second input signal is input to the control element 2B from the LINU terminal, the LINV terminal, and the LINW terminal, and the first input signal is input thereto from the HINU terminal, the HINV terminal, and the HINW terminal. The control element 2B generates the second driving signal (e.g., gate voltage) for driving the semiconductor elements 12A to 12C based on the first input signal and the second input signal that have been input thereto. Then, the generated second driving signal is input to the gates (sixth electrodes 123) of the semiconductor elements 12A to 12C.

A first voltage of the electrical signal provided to the HINU terminal (lead 4E), the HINV terminal (lead 4F), and the HINW terminal (lead 4G) is lower than a second voltage (power source voltage VCC) applied from the first VCC terminal (lead 4D) to drive the control element 2A. Moreover, the first voltage of the electrical signal provided to the LINU terminal (lead 4I), the LINV terminal (lead 4J), and the LINW terminal (lead 4K) is lower than the second voltage (power source voltage VCC) applied from the second VCC terminal (lead 4L) to drive the control element 2B.

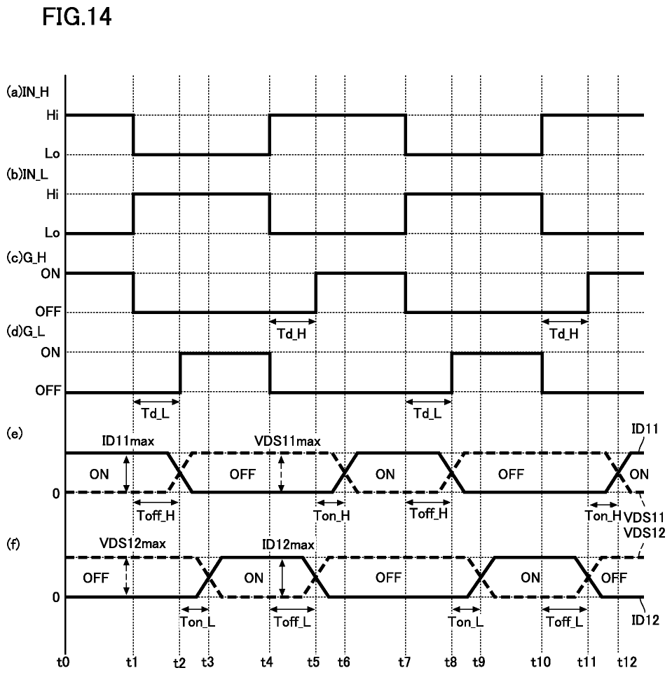

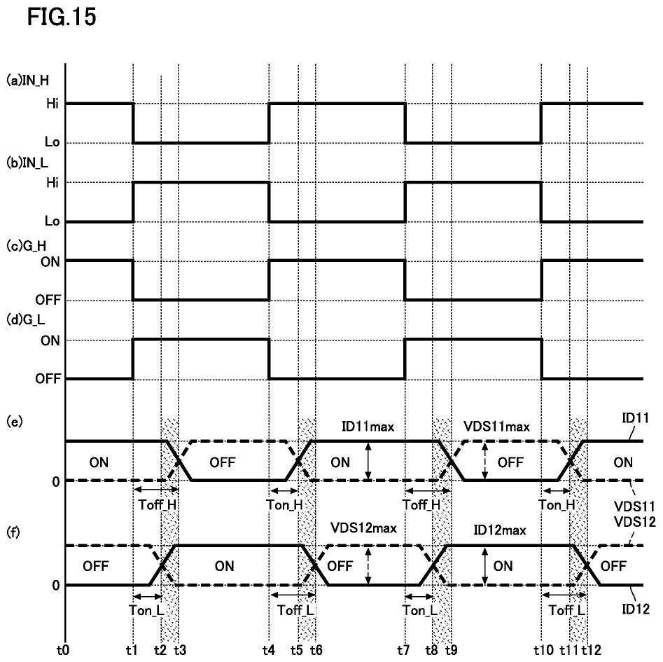

Next, an operational example of the semiconductor device A1 will be described with reference to FIGS. 14 and 15.

FIG. 14 is a timing chart showing an operational example of the semiconductor device A1. Although the operational example of the semiconductor device A1 shown in FIG. 14 indicates, for example, operational examples of the semiconductor element 11A and the semiconductor element 12A in the switching arm 10U (see FIG. 13), operational examples of the other switching arms 10V and 10W are similar thereto. However, the phases of the waveforms of the three switching arms 10U, 10V, and 10W are shifted from one another by, for example, 120°. FIG. 14(a) shows the waveform of a first input signal IN_H at an input end of the control element 2A. FIG. 14(b) shows the waveform of a second input signal IN_L at an input end of the control element 2B. FIG. 14(c) shows the waveform of a first driving signal G_H at an output end of the control element 2A. FIG. 14(d) shows the waveform of a second driving signal G_L at an output end of the control element 2B. FIG. 14€ shows the driving state of the semiconductor element 11. The solid line indicates the waveform of an electric current (drain current) ID11 in the semiconductor element 11, and the broken line indicates the waveform of a voltage (voltage between the drain and the source) VDS11 in the semiconductor element 11. FIG. 14(f) shows the driving state of the semiconductor element 12. The solid line indicates the waveform of an electric current (drain current) ID12 in the semiconductor element 12, and the broken line indicates the waveform of a voltage (voltage between the drain and the source) VDS12 in the semiconductor element 12. For the sake of convenience in understanding, FIG. 14 indicates the waveforms that have changed ideally, but in reality, a slight oscillation, phase shift, amplitude shift, or the like may occur.

As shown in FIGS. 14(a) and 14(b), the first input signal IN_H and the second input signal IN_L are rectangular pulse waves in which a high level and a low level are alternately switched between. In the first input signal IN_H of this embodiment, the high level corresponds to the on-level for instructing the electrical communication state of the semiconductor element 11, and the low level corresponds to the off-level for instructing the blocked state of the semiconductor element 11. Unlike this configuration, the low level may correspond to the on-level, and the high level may correspond to the off-level. In the example shown in FIG. 14, the duty ratios of the first input signal IN_H and the second input signal IN_L are 50%, but the duty ratios thereof can be changed as appropriate. As shown in FIGS. 14(a) and 14(b), the second input signal IN_L is an inverted signal obtained by inverting the first input signal IN_H. That is, while the first input signal IN_H is at a high level, the second input signal IN_L is at a low level. On the other hand, while the first input signal IN_H is at a low level, the second input signal IN_L is at a high level.

As shown in FIG. 14(c), in the first driving signal G_H, an on signal for bringing the semiconductor element 11 into the electrical communication state and an off signal for bringing the semiconductor element 11 into the blocked state are alternately switched. The first driving signal G_H is generated by the control element 2A and is output to the semiconductor element 11. In the example shown in FIG. 14, when the first input signal IN_H is switched from the high level to the low level (time points t1, t7), the first driving signal G_H is switched from the on signal to the off signal at the same time (or substantially the same time) as the switching of the first input signal IN_H. On the other hand, when the first input signal IN_H is switched from the low level to the high level (time points t4, t10), the first driving signal G_H is switched from the off signal to the on signal after at least a first period Td_H elapses. The first period Td_H will be described later.

As shown in FIG. 14(d), in the second driving signal G_L, an on-signal for bringing the semiconductor element 12 into the electrical communication state and an off-signal for bringing the semiconductor element 12 into the blocked state are alternately switched. The second driving signal G_L is generated by the control element 2B and is output to the semiconductor element 12. In the example shown in FIG. 14, when the second input signal IN_L is switched from the high level to the low level (time points t4, t10), the second driving signal G_L is switched from the on signal to the off signal at the same time (or substantially the same time) as the switching of the second input signal IN_L. On the other hand, when the second input signal IN_L is switched from the low level to the high level (time points t1, t7), the second driving signal G_L is switched from the off signal to the on signal after at least a second period Td_L elapses. The second period Td_L will be described later.

As shown in FIG. 14(e), after an off-state transition time Toff_H elapses since the first driving signal G_H is switched from the on signal to the off signal (time points t1, t7), the semiconductor element 11 is switched from the electrical communication state to the blocked state (time points t2, t8). Moreover, after an on-state transition time Ton_H elapses since the first driving signal G_H is switched from the off signal to the on signal (time points t5, t11), the semiconductor element 11 is switched from the blocked state to the electrical communication state (time points t6, t12). The off-state transition time Toff_H and the on-state transition time Ton_H vary as appropriate depending on, for example, the wiring distance between the control element 2A and the semiconductor element 11, and the switching speed of the semiconductor element 11. The switching speed refers to a speed at which the state of the semiconductor element 11 is actually changed after the first driving signal has been input to the third electrode 113 (gate electrode) of the semiconductor element 11. In the example shown in FIG. 14(e), the electrical communication state and the blocked state of the semiconductor element 11 are switched between when the electric current ID11 and the voltage VDS11 in the semiconductor element 11 intersect each other, but the determining condition for the switching between the electrical communication state and the blocked state of the semiconductor element 11 is not limited thereto. This determining condition may be set as, for example, timing at which the electric current ID11 is zero, or timing at which the electric current ID11 is smaller than or equal to a threshold (or a predetermined ratio to the maximum value ID11max of the electric current ID11). Alternatively, the determining condition may be set as timing at which the voltage VDS11 is the maximum value VDS11max of the voltage VDS11, or timing at which the voltage VDS11 is larger than or equal to a threshold (or a predetermined ratio to the maximum value VDS11max of the voltage VDS11).

As shown in FIG. 14(f), after an off-state transition time Toff_L elapses since the second driving signal G_L is switched from the on signal to the off signal (time points t4, t10), the semiconductor element 12 is switched from the electrical communication state to the blocked state (time points t5, t11). Moreover, after an on-state transition time Ton_L elapses since the second driving signal G_L is switched from the off signal to the on signal (time points t2, t8), the semiconductor element 12 is switched from the blocked state to the electrical communication state (time points t3, t9). The off-state transition time Toff_L and the on-state transition time Ton_L vary as appropriate depending on, for example, the wiring distance between the control element 2B and the semiconductor element 12, and the switching speed of the semiconductor element 12. The switching speed refers to a speed at which the state of the semiconductor element 12 is actually changed after the second driving signal has been input to the sixth electrode 123 (gate electrode) of the semiconductor element 12. In the example shown in FIG. 14(f), the electrical communication state and the blocked state of the semiconductor element 12 are switched between when the electric current ID12 and the voltage VDS12 in the semiconductor element 12 intersect each other, but the determining condition for the switching between the electrical communication state and the blocked state of the semiconductor element 12 is not limited thereto. This determining condition may be set as, for example, timing at which the electric current ID12 is zero, or timing at which the electric current ID12 is smaller than or equal to a threshold (or a predetermined ratio to the maximum value ID12max of the electric current ID12). Alternatively, the determining condition may be set as timing at which the voltage VDS12 is the maximum value VDS12max of the voltage VDS12, or timing at which the voltage VDS12 is larger than or equal to a threshold (or a predetermined ratio to the maximum value VDS12max of the voltage VDS12).

In the semiconductor device A1, the first input signal IN_H is input to the control element 2A, and the second input signal IN_L is also input thereto. Then, the control element 2A infers the driving state of the semiconductor element 12 based on the second input signal IN_L, and if it is determined that the semiconductor element 12 is in the electrical communication state, the control element 2A delays the switching of the semiconductor element 11 from the blocked state to the electrical communication state.

For example, even when the second input signal IN_L is switched from the high level to the low level at time points t4 and t10, the control element 2A determines that the semiconductor element 12 is in the electrical communication state until the predetermined first period Td_H elapses. The first period Td_H is set based on the off-state transition time Toff_L at the time when the semiconductor element 12 is switched to the blocked state, and in the example shown in FIG. 14, the first period Td_H is the same (or substantially the same) as the off-state transition time Toff_L. The off-state transition time Toff_L is an example of a “first transition time”. Even when the first input signal IN_H is switched from the low level to the high level within the first period Td_H (between time point t4 and time point t5, and between time point t10 and time point t11), that is, within the period in which it is determined that the semiconductor element 12 is in the electrical communication state, the control element 2A does not switch the first driving signal G_H from the off signal to the on signal (that is, delays the switching of the first driving signal). Thus, the first driving signal G_H generated by the control element 2A is not switched from the off signal to the on signal within a period (first period Td_H) when it is determined that the semiconductor element 12 is in the electrical communication state. That is, within a period in which the semiconductor element 12 is in the electrical communication state, the control element 2A generates the first driving signal G_H such that the semiconductor element 11 is not in the electrical communication state.

Then, when the first period Td_H elapses at time points t5 and t11, the semiconductor element 12 is switched from the electrical communication state to the blocked state as shown in FIG. 14(f). Therefore, the control element 2A determines that the semiconductor element 12 is not in the electrical communication state, and switches the first driving signal G_H from the off signal to the on signal. In the example shown in FIG. 14, the first input signal IN_H is switched from the low level to the high level at the same time as the second input signal IN_L is switched from the high level to the low level. Therefore, the timing (time points t5, t11) at which the first driving signal G_H is switched from the off signal to the on signal is delayed by the first period Td_H from the timing (time points t4, t10) at which the first input signal IN_H is switched from the low level to the high level. Note that, if the first input signal IN_H is not switched from the low level to the high level within the first period Td_H but is switched after the first period Td_H has elapsed unlike the example shown in FIG. 14, it is sufficient that the control element 2A switches the first driving signal G_H from the off signal to the on signal at the same time as the first input signal IN_H is switched. That is, it is sufficient that the timing at which the first driving signal G_H is switched from the off signal to the on signal is set to be the same (or substantially the same) as the timing at which the first input signal IN_H is switched from the low level to the high level.

When the first driving signal G_H is switched from the off signal to the on signal (time points t5, t11), the semiconductor element 11 is switched from the blocked state to the electrical communication state after the on-state transition time Ton_H has elapsed (time points t6, t12) as shown in FIG. 14(e). Due to the semiconductor device A1 operating as described above, the semiconductor element 11 is switched from the blocked state to the electrical communication state after the semiconductor element 12 has been switched from the electrical communication state to the blocked state.

In the semiconductor device A1, the first input signal IN_H is input to the control element 2B, and the second input signal IN_L is also input thereto. Then, the control element 2B infers the driving state of the semiconductor element 11 based on the first input signal IN_H, and if it is determined that the semiconductor element 11 is in the electrical communication state, the control element 2B delays the switching of the semiconductor element 12 from the blocked state to the electrical communication state.

For example, even when the first input signal IN_H is switched from the high level to the low level at time points t1 and t7, the control element 2B determines that the semiconductor element 11 is in the electrical communication state until the predetermined second period Td_L elapses. The second period Td_L is set based on the off-state transition time Toff_H at the time when the semiconductor element 11 is switched to the blocked state, and in the example shown in FIG. 14, the second period Td_L is the same (or substantially the same) as the off-state transition time Toff_H. The off-state transition time Toff_H is an example of a “second transition time”. Even when the second input signal IN_L is switched from the low level to the high level within the second period Td_L (between time point t1 and time point t2, and between time point t7 and time point t8), that is, within the period in which it is determined that the semiconductor element 11 is in the electrical communication state, the control element 2B does not switch the second driving signal G_L from the off signal to the on signal. Thus, the second driving signal G_L generated by the control element 2B is not switched from the off signal to the on signal within a period (second period Td_L) when it is determined that the semiconductor element 11 is in the electrical communication state. That is, within a period in which the semiconductor element 11 is in the electrical communication state, the control element 2B generates the second driving signal G_L such that the semiconductor element 12 is not in the electrical communication state.

Then, when the second period Td_L elapses at time points t2 and t8, the semiconductor element 11 is switched from the electrical communication state to the blocked state as shown in FIG. 14(e). Therefore, the control element 2B determines that the semiconductor element 11 is not in the electrical communication state, and switches the second driving signal G_L from the off signal to the on signal. In the example shown in FIG. 14, the second input signal IN_L is switched from the low level to the high level at the same time as the first input signal IN_H is switched from the high level to the low level. Therefore, the timing (time points t2, t8) at which the second driving signal G_L is switched from the off signal to the on signal is delayed by the second period Td_L from the timing (time points t1, t7) at which the second input signal IN_L is switched from the low level to the high level. Note that, if the second input signal IN_L is not switched from the low level to the high level within the second period Td_L but is switched after the second period Td_L has elapsed unlike the example shown in FIG. 14, it is sufficient that the control element 2B switches the second driving signal G_L from the off signal to the on signal at the same time as the second input signal IN_L is switched. That is, it is sufficient that the timing at which the second driving signal G_L is switched from the off signal to the on signal is set to be the same (or substantially the same) as the timing at which the second input signal IN_L is switched from the low level to the high level.

When the second driving signal G_L is switched from the off signal to the on signal (time points t2, t8), the semiconductor element 12 is switched from the blocked state to the electrical communication state after the on-state transition time Ton_L has elapsed (time points t3, t9) as shown in FIG. 14(f). Due to the semiconductor device A1 operating as described above, the semiconductor element 12 is switched from the blocked state to the electrical communication state after the semiconductor element 11 has been switched from the electrical communication state to the blocked state.

Next, an operational example of a semiconductor device A0 (e.g., the semiconductor device disclosed in Patent Document 1) that is different from the semiconductor device A1 will be described with reference to FIG. 15. FIG. 15 is a timing chart showing an operational example of the semiconductor device A0. In the semiconductor device A0, the second input signal is not input to the control element 2A, and the first input signal is not input to the control element 2B. FIGS. 15(a) to 15(f) show waveforms corresponding to FIGS. 14(a) to 14(f), respectively. Note that time points t0 to t12 in FIG. 14 do not correlate with time points t0 to t12 in FIG. 15.

In the semiconductor device A0, the second input signal IN_L is not input to the control element 2A, and thus the control element 2A cannot determine if the semiconductor element 12 is in the electrical communication state. Therefore, as shown in FIGS. 15(a) and 15(c), the waveform of the generated first driving signal G_H has the same shape (or substantially the same shape) as the waveform of the first input signal IN_H. Moreover, the first input signal IN_H is not input to the control element 2B, and thus the control element 2B cannot determine if the semiconductor element 11 is in the electrical communication state. Therefore, as shown in FIGS. 15(b) and 15(d), the waveform of the generated second driving signal G_L has the same shape as the waveform of the second input signal IN_L. After the off-state transition time Toff_H elapses since the first driving signal G_H is switched from the on signal to the off signal (time points t1, t7), the semiconductor element 11 is switched from the electrical communication state to the blocked state (time points t3, t9). Moreover, after the on-state transition time Ton_H elapses since the first driving signal G_H is switched from the off signal to the on signal (time points t4, t10), the semiconductor element 11 is switched from the blocked state to the electrical communication state (time points t5, t11). On the other hand, after the on-state transition time Ton_L elapses since the second driving signal G_L is switched from the off signal to the on signal (time points t1, t7), the semiconductor element 12 is switched from the blocked state to the electrical communication state (time points t2, t8). Moreover, after the off-state transition time Toff_L elapses since the second driving signal G_L is switched from the on signal to the off signal (time points t4, t10), the semiconductor element 12 is switched from the electrical communication state to the blocked state (time points t6, t12). As a result, in the semiconductor device A0, there are periods in which the semiconductor element 11 and the semiconductor element 12 are simultaneously in the electrical communication state, between time point t2 (t8) and time point t3 (t9) and between time point t5 (t11) and time point t6 (t12), as is understood from FIGS. 15(e) and 15(f) (see dotted regions in FIG. 15). Accordingly, it can be seen that, in the semiconductor device A1, a period in which the semiconductor element 11 and the semiconductor element 12 are simultaneously in the electrical communication state can be suppressed as shown in FIG. 14 by inputting not only the first input signal but also the second input signal to the control element 2A and inputting not only the second input signal but also the first input signal to the control element 2B.

The following describes the functions and effects of the semiconductor device A1.

In the semiconductor device A1, when the second input signal IN_L is input to the control element 2A and it is determined that the semiconductor element 12 is in the electrical communication state based on the second input signal IN_L, the control element 2A delays the switching of the semiconductor element 11 from the blocked state to the electrical communication state. With this configuration, when it is determined that the semiconductor element 12 is in the electrical communication state, the switching of the semiconductor element 11 from the blocked state to the electrical communication state is suppressed. Accordingly, the semiconductor element 11 and the semiconductor element 12 are inhibited from being simultaneously in the electrical communication state when the semiconductor element 11 is switched from the blocked state to the electrical communication state. That is, with the semiconductor device A1, it is possible to suppress an arm short-circuit caused by simultaneous turning-on of the upper and lower arms when the semiconductor element 11 is switched from the blocked state to the electrical communication state.

In the semiconductor device A1, the control element 2A does not switch the semiconductor element 11 to the electrical communication state until the predetermined first period Td_H elapses after the second input signal IN_L has been switched from the on-level to the off-level. In this embodiment, the on-level corresponds to the high level, and the off-level corresponds to the low level. The first period Td_H is set based on the off-state transition time Toff_L, which elapses before the semiconductor element 12 is switched to the blocked state. In the semiconductor device A1, even when the second input signal IN_L is switched from the on-level to the off-level, the semiconductor element 12 is not brought into the blocked state until the off-state transition time Toff_L elapses. Accordingly, the control element 2A is configured to determine that the semiconductor element 12 is in the electrical communication state until the first period Td_H, which is set based on the off-state transition time Toff_L, elapses. Thus, with the semiconductor device A1, it is possible to delay the switching of the semiconductor element 11 from the blocked state to the electrical communication state during the period in which the semiconductor element 12 is determined to be in the electrical communication state, by not switching the semiconductor element 11 to the electrical communication state during the first period Td_H.

In the semiconductor device A1, when the first input signal IN_H is input to the control element 2B and it is determined that the semiconductor element 11 is in the electrical communication state based on the first input signal IN_H, the control element 2B delays the switching of the semiconductor element 12 from the blocked state to the electrical communication state. With this configuration, when it is determined that the semiconductor element 11 is in the electrical communication state, the switching of the semiconductor element 12 from the blocked state to the electrical communication state is suppressed. Accordingly, the semiconductor element 11 and the semiconductor element 12 are inhibited from being simultaneously in the electrical communication state when the semiconductor element 12 is switched from the blocked state to the electrical communication state. That is, with the semiconductor device A1, it is possible to suppress an arm short-circuit caused by simultaneous turning-on of the upper and lower arms when the semiconductor element 12 is switched from the blocked state to the electrical communication state.

In the semiconductor device A1, the control element 2B does not switch the semiconductor element 12 to the electrical communication state until the second period Td_L elapses after the first input signal IN_H has been switched from the on-level to the off-level. In this embodiment, the on-level corresponds to the high level, and the off-level corresponds to the low level. The second period Td_L is set based on the off-state transition time Toff_H, which elapses before the semiconductor element 11 is switched to the blocked state. In the semiconductor device A1, even when the first input signal IN_H is switched from the on-level to the off-level, the semiconductor element 11 is not brought into the blocked state until the off-state transition time Toff_H elapses. Accordingly, the control element 2B is configured to determine that the semiconductor element 11 is in the electrical communication state until the second period Td_L, which is set based on the off-state transition time Toff_H, elapses. Thus, with the semiconductor device A1, it is possible to delay the switching of the semiconductor element 12 from the blocked state to the electrical communication state during the period in which the semiconductor element 11 is determined to be in the electrical communication state, by not switching the semiconductor element 12 to the electrical communication state during the second period Td_L.

In the semiconductor device A1, the control element 2A is in electrical communication with the lead 4E (4F, 4G) as well as the lead 4I (4J, 4K). The first input signal IN_H is input to the lead 4E (4F, 4G), and the second input signal IN_L is input to the lead 4I (4J, 4K). The control element 2A is in electrical communication with the lead 4I (4J, 4K) via, for example, the connection members 6 (wires 6J). With this configuration, the first input signal IN_H and the second input signal IN_L can be input to the control element 2A. Moreover, the control element 2B is in electrical communication with the lead 4E (4F, 4G) as well as the lead 4I (4J, 4K). The control element 2B is in electrical communication with the lead 4E (4F, 4G) via, for example, the connection members 6 (wires 6K). With this configuration, the first input signal IN_H and the second input signal IN_L can be input to the control element 2B.

In the semiconductor device A1, the second input signal IN_L is an inverted signal obtained by inverting the first input signal IN_H. That is, with the semiconductor device A1, it is possible to suppress an arm short-circuit caused by simultaneous turning-on of the upper and lower arms by inhibiting the semiconductor element 11 and the semiconductor element 12 that are connected in series from being simultaneously in the electrical communication state, without providing dead-time periods in advance in the first input signal IN_H and the second input signal IN_L that are input from an external gate control circuit.

In the example shown in the first embodiment, ends at one side of the wires 6J are joined to the control element 2A, and ends on the other side are joined to the pad portions 431, 43J, and 43K. However, the ends on the other side may be joined to the coupling portions 441, 44J, and 44K instead of the pad portions 431, 43J, and 43K, or directly to the control element 2B. As the ends on the other side are connected as appropriate to positions that are closer to the control element 2A in accordance with the shapes of the leads 4I, 4J, and 4K, the lengths of the wires 6J can be further reduced. Similarly, in the example shown in the first embodiment, ends at one side of the wires 6K are joined to the control element 2B, and ends on the other side are joined to the pad portions 43E, 43F, and 43G. However, the ends on the other side may be joined to the coupling portions 44E, 44F, and 44G instead of the pad portions 43E, 43F, and 43G, or directly to the control element 2A. As the ends on the other side are connected as appropriate to positions that are closer to the control element 2A in accordance with the shapes of the leads 4E, 4F, and 4G, the lengths of the wires 6K can be further reduced.

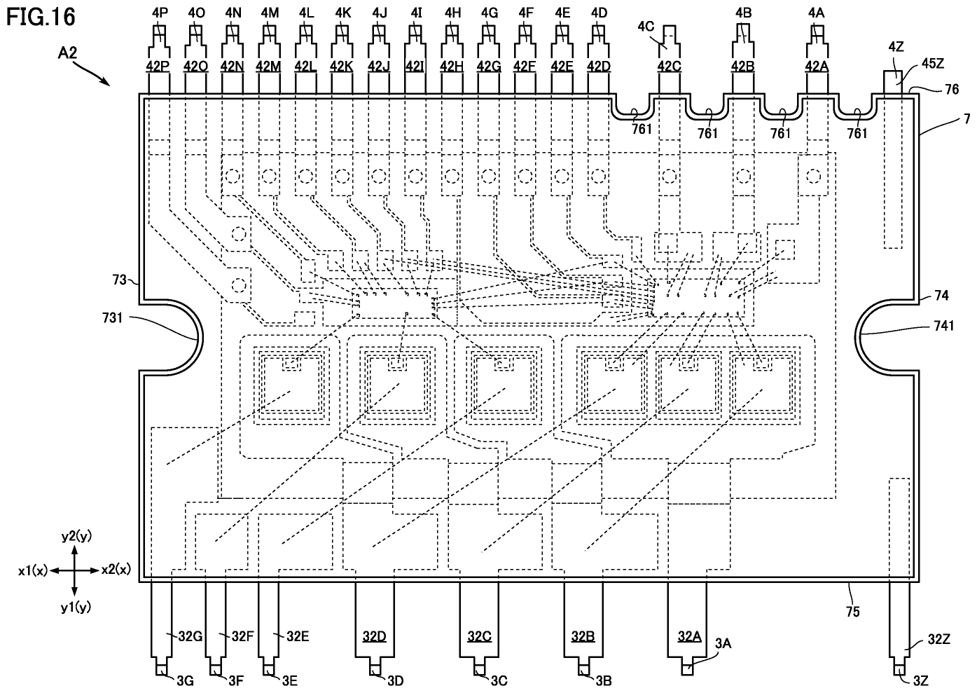

FIGS. 16 to 22 show a semiconductor device A2 according to a second embodiment. As shown in these diagrams, the semiconductor device A2 includes the plurality of semiconductor elements 11 and 12, the two control elements 2A and 2B, the plurality of electronic components 29, the plurality of leads 3A to 3G and 3Z, the plurality of leads 4A to 4P, the support substrate 51, a wiring pattern 52, the plurality of connection members 6, and a sealing member 7. In the examples shown in FIGS. 16 to 22, the semiconductor device A2 does not include the plurality of protection elements 13, but may include a plurality of protection elements 13 as in the case of the semiconductor device A1.

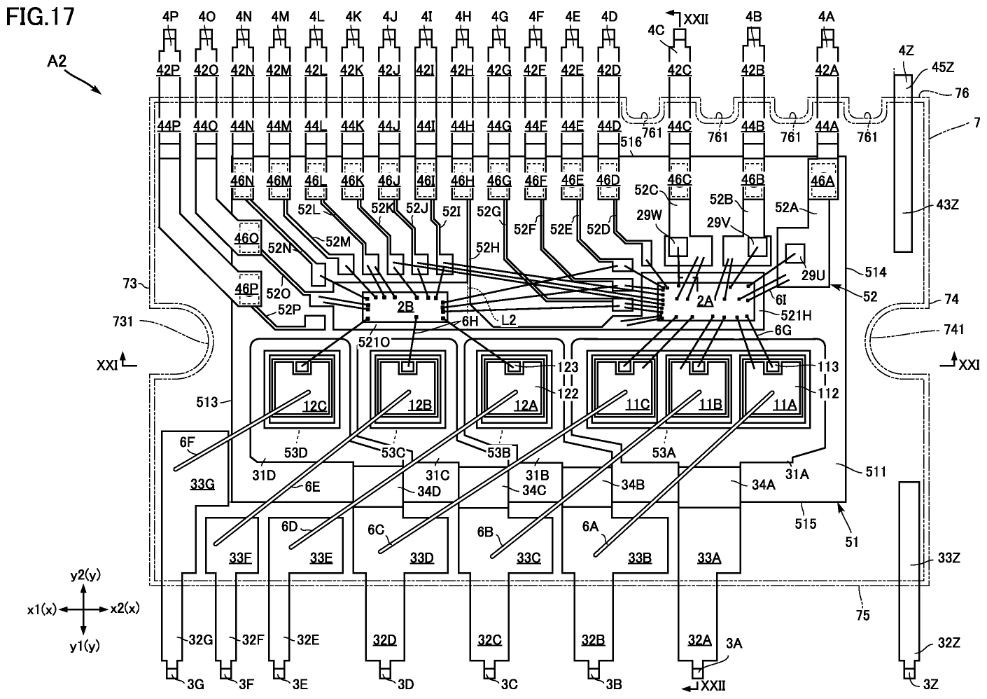

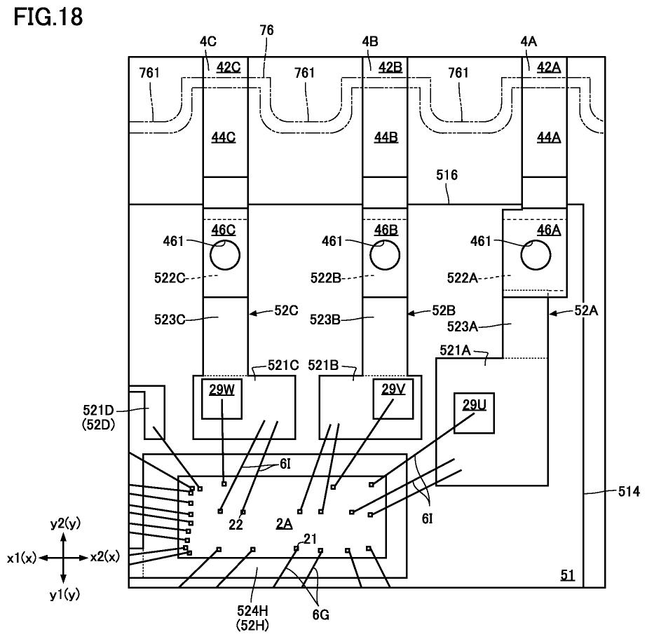

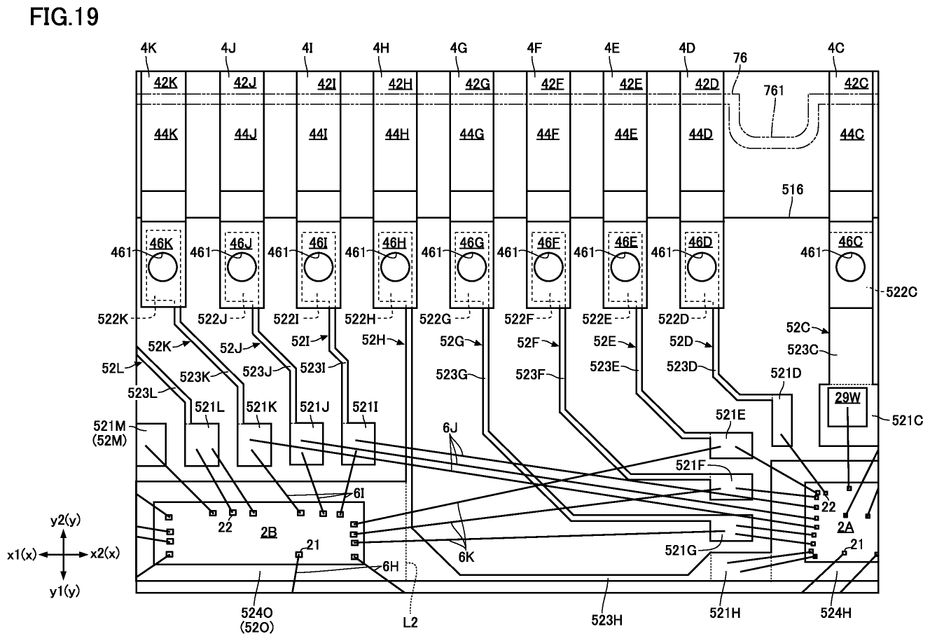

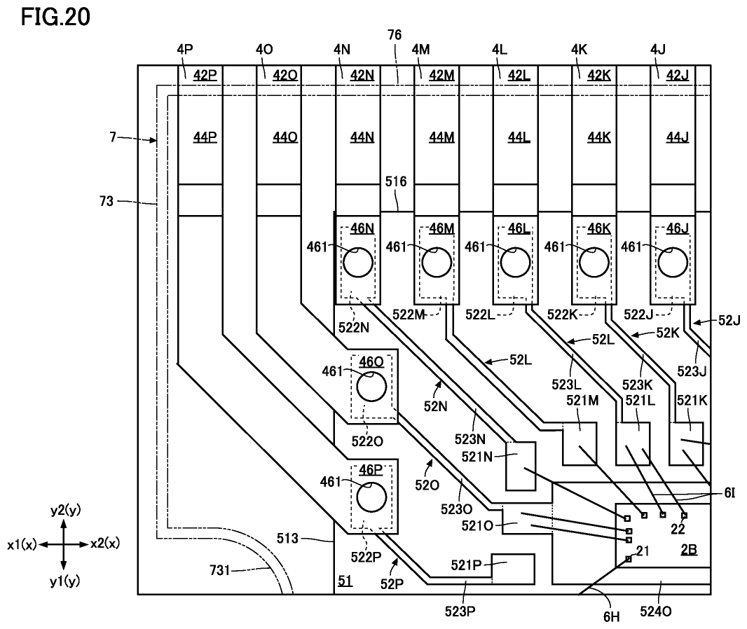

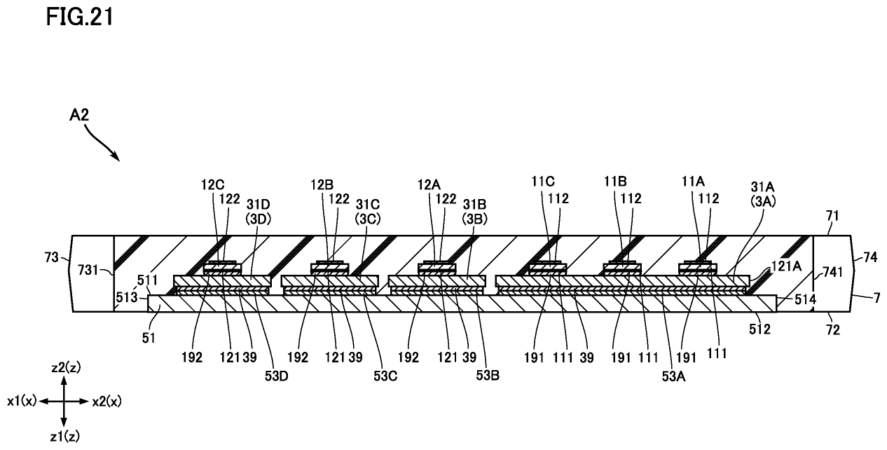

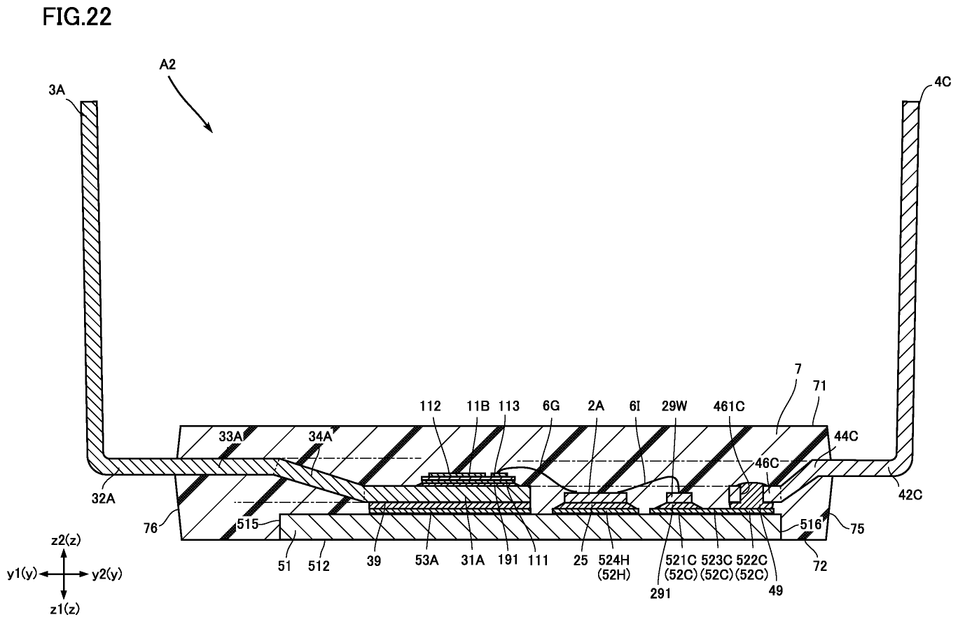

FIG. 16 is a plan view showing the semiconductor device A2. FIG. 17 shows the plan view of FIG. 16 in which the sealing member 7 is indicated by imaginary lines (two-dot dash lines). FIG. 18 is a partially enlarged view in which a portion of FIG. 17 is enlarged. FIG. 19 is a partially enlarged view in which a portion of FIG. 17 is enlarged. FIG. 20 is a partially enlarged view in which a portion of FIG. 17 is enlarged. FIG. 21 is a cross-sectional view taken along line XXI-XXI in FIG. 17. FIG. 22 is a cross-sectional view taken along line XXII-XXII in FIG. 17.

The wiring pattern 52 is formed on the first surface 511 of the support substrate 51. The wiring pattern 52 is made of a conductive material. The wiring pattern 52 is covered by the sealing member 7. The wiring pattern 52 includes at least a wiring portion 52E (52F, 52G) serving as a first wiring portion, a wiring portion 521 (52J, 52K) serving as a second wiring portion, and wiring portions 52H and 520 serving as a third wiring portion. In this embodiment, a plurality of wiring portions 52A to 52P and a plurality of joining portions 53A to 53D are provided.

The plurality of wiring portions 52A to 52P are formed on the support substrate 51. In this embodiment, the wiring portions 52A to 52P are formed on the first surface 511 of the support substrate 51. The wiring portions 52A to 52P are made of a conductive material. There is no particular limitation on the conductive material used to form the wiring portions 52A to 52P, and examples thereof include conductive materials containing Ag, Cu, Au, and the like. In the following description, examples in which the wiring portions 52A to 52P contain Ag will be described. Note that the wiring portions 52A to 52P may contain Cu instead of Ag, or Au instead of Ag or Cu. Alternatively, the wiring portions 52A to 52P may contain Ag—Pt or Ag—Pd. Moreover, there is no limitation on a method of forming the wiring portions 52A to 52P, and the wiring portions 52A to 52P are formed by, for example, printing a paste containing these metals and then firing it.

Out of the plurality of wiring portions 52A to 52P, the wiring portion 52H and the wiring portion 520 are integrally formed, and the others are spaced apart from one another. An additional line L2 shown in FIGS. 17 and 19 indicates the boundary between the wiring portion 52H and the wiring portion 520, namely a portion where these wiring portions are integrally connected to each other. Unlike this example, the wiring portion 52H and the wiring portion 520 may be spaced apart from each other.

As shown in FIG. 17, the wiring portion 52A, the wiring portion 52B, and the wiring portion 52C are arranged on the x2 side with respect to the wiring portion 52D.

As shown in FIG. 18, the wiring portion 52A includes two pad portions 521A and 522A, and a coupling portion 523A. The wires 61 connected to the control element 2A, and the electronic component 29U are joined to the pad portion 521A, and the lead 4A is joined to the pad portion 522A. The pad portion 522A is located on a side opposite to the leads 3A to 3G and 3Z with respect to the pad portion 521A in the y direction. In the example shown in FIG. 18, the pad portions 521A and 522A have a rectangular shape in a plan view. The coupling portion 523A couples the pad portion 521A and the pad portion 522A.

As shown in FIG. 18, the wiring portion 52B includes two pad portions 521B and 522B, and a coupling portion 523B. The wires 61 connected to the control element 2A, and the electronic component 29V are joined to the pad portion 521B, and the lead 4B is joined to the pad portion 522B. The pad portion 522B is located on a side opposite to the leads 3A to 3G and 3Z with respect to the pad portion 521B in the y direction. In the example shown in FIG. 18, the pad portions 521B and 522B have a rectangular shape in a plan view. The coupling portion 523B couples the pad portion 521B and the pad portion 522B.

As shown in FIGS. 18, 19, and 22, the wiring portion 52C includes two pad portions 521C and 522C, and a coupling portion 523C. The wires 61 connected to the control element 2A, and the electronic component 29W are joined to the pad portion 521C, and the lead 4C is joined to the pad portion 522C. The pad portion 522C is located on a side opposite to the leads 3A to 3G and 3Z with respect to the pad portion 521C in the y direction. In the example shown in FIG. 18, the pad portions 521C and 522C have a rectangular shape in a plan view. The coupling portion 523C couples the pad portion 521C and the pad portion 522C.

As shown in FIGS. 17 and 19, a wiring portion 52D is arranged on the x1 side with respect to the wiring portion 52C. As shown in FIG. 19, the wiring portion 52D includes two pad portions 521D and 522D, and a coupling portion 523D. The wires 61 connected to the control element 2A are joined to the pad portion 521D, and the lead 4D is joined to the pad portion 522D. The pad portion 522D is located on a side opposite to the leads 3A to 3G and 3Z with respect to the pad portion 521D in the y direction. In the example shown in FIG. 19, the pad portions 521D and 522D have a rectangular shape in a plan view. The coupling portion 523D couples the pad portion 521D and the pad portion 522D.

As shown in FIGS. 17 and 19, a wiring portion 52E, the wiring portion 52F, and the wiring portion 52G are arranged on the x1 side with respect to the wiring portion 52D. The following is a detailed description of the wiring portion 52E, and the wiring portions 52F and 52G also include the similar constituent parts. In this case, reference numerals obtained by changing the letter “E” in the reference numerals for the constituent parts of the wiring portion 52E to “F” or “G” are used for the constituent parts of the wiring portions 52F and 52G.

As shown in FIG. 19, the wiring portion 52E includes two pad portions 521E and 522E, and a coupling portion 523E. Although the detailed descriptions are omitted as described above, the wiring portion 52F includes two pad portions 521F and 522F and a coupling portion 523F, and the wiring portion 52G includes two pad portions 521G and 522G and a coupling portion 523G, as shown in FIG. 19.

The wires 61 connected to the control element 2A and the wires 6K connected to the control element 2B are joined to the pad portion 521E, and the lead 4E is joined to the pad portion 522E. Note that the lead 4F is joined to the pad portion 522F, and the lead 4G is joined to the pad portion 522G. The pad portion 522E is located on a side opposite to the leads 3A to 3G and 3Z with respect to the pad portion 521E in the y direction. In the example shown in FIG. 18, the pad portions 521E and 522E have a rectangular shape in a plan view. The coupling portion 523E couples the pad portion 521E and the pad portion 522E.

The control element 2A is mounted on the wiring portion 52H. As shown in FIGS. 18 and 19, the wiring portion 52H includes two pad portions 521H and 522H, a coupling portion 523H, and a mounting portion 524H.

The wires 61 connected to the control element 2A are joined to the pad portion 521H, and the lead 4H is joined to the pad portion 522H. The pad portion 522H is located on a side opposite to the leads 3A to 3G and 3Z with respect to the pad portion 521H in the y direction. In the example shown in FIG. 19, the pad portions 521H and 522H have a rectangular shape in a plan view. The pad portion 521H is connected to the mounting portion 524H. The coupling portion 523H couples the pad portion 521H and the pad portion 522H. The control element 2A is mounted on the mounting portion 524H. The control element 2A is adhered to the mounting portion 524H using the joining material 25.

The control element 2B is mounted on the wiring portion 520. As shown in FIGS. 19 and 20, the wiring portion 520 includes two pad portions 5210 and 5220, a coupling portion 5230, and a mounting portion 5240.

The wires 61 connected to the control element 2B are joined to the pad portion 5210, and the lead 4O is joined to the pad portion 5220. The pad portion 5220 is located on a side opposite to the leads 3A to 3G with respect to the pad portion 5210 in the y direction. In the example shown in FIG. 20, the pad portions 5210 and 5220 have a rectangular shape in a plan view. The pad portion 5210 is connected to the mounting portion 5240. The coupling portion 5230 couples the pad portion 5210 and the pad portion 5220. The control element 2B is mounted on the mounting portion 5240. The control element 2B is adhered to the mounting portion 5240 using the joining material 25.

As shown in FIGS. 17 and 19, the wiring portion 521, the wiring portion 52J, and the wiring portion 52K are arranged on the x1 side with respect to the wiring portion 52H. The following is a detailed description of the wiring portion 521, and the wiring portions 52J and 52K also include the similar constituent parts. In this case, reference numerals obtained by changing the letter “I” in the reference numerals for the constituent parts of the wiring portion 521 to “J” or “K” are used for the constituent parts of the wiring portions 52J and 52K.

As shown in FIG. 19, the wiring portion 521 includes two pad portions 5211 and 5221, and a coupling portion 5231. Although the detailed descriptions are omitted as described above, the wiring portion 52J includes two pad portions 521J and 522J and a coupling portion 523J, and the wiring portion 52K includes two pad portions 521K and 522K and a coupling portion 523K, as shown in FIG. 19.

The wires 61 connected to the control element 2B and the wires 6J connected to the control element 2B are joined to the pad portion 5211, and the lead 4I is joined to the pad portion 5221. Note that the lead 4J is joined to the pad portion 522J, and the lead 4K is joined to the pad portion 522K. The pad portion 5221 is located on a side opposite to the leads 3A to 3G and 3Z with respect to the pad portion 5211 in the y direction. In the example shown in FIG. 19, the pad portions 5211 and 5221 have a rectangular shape in a plan view. The coupling portion 5231 couples the pad portion 5211 and the pad portion 5221.

As shown in FIGS. 17 and 20, the plurality of wiring portions 52L to 52N and 52P are arranged on the x1 side with respect to the wiring portion 52K. The following is a detailed description of the wiring portion 52L, and the wiring portions 52M, 52N, and 52P also include the similar constituent parts. In this case, reference numerals obtained by changing the letter “L” in the reference numerals for the constituent parts of the wiring portion 52L to “M”, “N”, or “P” are used for the constituent parts of the wiring portions 52M, 52N, and 52P.

As shown in FIG. 20, the wiring portion 52L includes two pad portions 521L and 522L, and a coupling portion 523L. Although the detailed descriptions are omitted as described above, the wiring portion 52M includes two pad portions 521M and 522M and a coupling portion 523M, the wiring portion 52N includes two pad portions 521N and 522N and a coupling portion 523N, and the wiring portion 52P includes two pad portions 521P and 522P and a coupling portion 523P, as shown in FIG. 20.

The wires 61 connected to the control element 2B are joined to the pad portion 521L. However, in the example shown in FIG. 20, the wires 61 are not joined to the pad portion 521P. The lead 4L is joined to the pad portion 522L. Note that the lead 4M is joined to the pad portion 522M, the lead 4N is joined to the pad portion 522N, and the lead 4P is joined to the pad portion 522P. The pad portion 522L is located on a side opposite to the leads 3A to 3G and 3Z with respect to the pad portion 521L in the y direction. In the example shown in FIG. 20, the pad portions 521L and 522L have a rectangular shape in a plan view. The coupling portion 523L couples the pad portion 521L and the pad portion 522L.

As shown in FIGS. 17 to 20, the pad portions 522A to 522P are arranged along the peripheral edge of the support substrate 51 in a plan view.

The plurality of joining portions 53A to 53D are formed on the support substrate 51. As shown in FIGS. 21 and 22, the joining portions 53A to 53D are formed on the first surface 511 of the support substrate 51 as in the case of the wiring portions 52A to 52P. As is understood from FIGS. 17 and 21, the joining portion 53A is arranged below the mounting portion 31A of the lead 3A, the joining portion 53B is arranged below the mounting portion 31B of the lead 3B, the joining portion 53C is arranged below the mounting portion 31C of the lead 3C, and the joining portion 53D is arranged below the mounting portion 31D of the lead 3D. There is no particular limitation on the constituent materials of the joining portions 53A to 53D, and the joining portions 53A to 53D are made of a material that can join the support substrate 51 and the leads 3A to 3D. The joining portions 53A to 53D are made of, for example, a conductive material. There is no particular limitation on the conductive material used to form the joining portions 53A to 53D, and examples thereof include conductive materials containing Ag, Cu, Au, and the like. The joining portions 53A to 53D contain the same conductive material as the conductive material used to form the wiring portions 52A to 52P. Note that the joining portions 53A to 53D may contain copper instead of silver, or gold instead of silver or copper. Alternatively, the wiring portions 52A to 52P may contain Ag—Pt or Ag—Pd. Moreover, there is no limitation on a method of forming the joining portions 53A to 53D, and the joining portions 53A to 53D are formed by printing a paste containing these metals and then firing it, for example, as in the case of the wiring portions 52A to 52P.

In the semiconductor device A2, the plurality of leads 4A to 4P are joined to the wiring pattern 52. Moreover, the semiconductor device A2 further includes a lead 4Z compared with the semiconductor device A1.

As shown in FIG. 17, the plurality of leads 4A to 4P are arranged on the x1 side with respect to the lead 4Z. The following is a detailed description of the lead 4A, and the other leads 4B to 4P also include the similar constituent parts. In this case, reference numerals obtained by changing the letter “A” in the reference numerals for the constituent parts of the lead 4A to “B” to “P” are used for the constituent parts of the leads 4B to 4P.

As shown in FIG. 17, etc., the lead 4A includes the terminal portion 42A, a coupling portion 44A, and a joining portion 46A. The terminal portion 42A of the semiconductor device A2 is configured in the same manner as the terminal portion 42A of the semiconductor device A1. The joining portion 46A is joined to the pad portion 522A of the wiring portion 52A. Similarly, the joining portion 46B (46C to 46P) is joined to the pad portion 522B (522C to 522P) of the wiring portion 52B (52C to 52P). The joining portion 46A (46B to 46P) is joined to the pad portion 522A (522B to 522P) via a conductive joining material 49. Examples of the conductive joining material 49 include a solder, metal paste materials, and sintered metals (see FIG. 22). In the example shown in FIG. 18, the joining portion 46A is provided with a through hole 461A, but does not have to be provided with this through hole 461A. The through hole 461A passes through the joining portion 46A in the z direction (see FIG. 22). Similarly, as shown in FIGS. 18 to 20, the joining portion 46B (46C to 46P) is provided with a through hole 461B (461C to 461P), but does not have to be provided with this through hole 461B (461C to 461P). The coupling portion 44A couples the terminal portion 42A and the joining portion 46A.

The lead 4Z is arranged on the x2 side with respect to the lead 4A. The lead 4Z is in electrical communication with none of the plurality of semiconductor elements 11 and 12 and neither of the two control elements 2A and 2B. As shown in FIG. 17, the lead 4Z includes a pad portion 43Z and a protruding portion 45Z. The pad portion 43Z and the protruding portion 45Z are connected to each other.

The pad portion 43Z is covered by the sealing member 7. As shown in FIG. 17, the pad portion 43Z does not overlap the support substrate 51 in a plan view.

As shown in FIGS. 16 and 17, the protruding portion 45Z extends toward the y2 side from the pad portion 43Z, and protrudes from the sealing member 7.

The circuit configuration and the operational example of the semiconductor device A2 are the same as the circuit configuration (see FIG. 13) and the operational example (see FIG. 14) of the semiconductor device A1. However, since the semiconductor device A2 does not include the plurality of protection elements 13, the circuit configuration thereof corresponds to the circuit configuration of the semiconductor device A1 shown in FIG. 13 from which the plurality of protection elements 13 are removed.

The semiconductor device A2 can exhibit the same effects as those of the semiconductor device A1. Accordingly, with the semiconductor device A2, it is possible to suppress an arm short-circuit caused by simultaneous turning-on of the upper and lower arms as in the case of the semiconductor device A1.

The semiconductor device A2 includes the support substrate 51 and the wiring pattern 52 formed on the first surface 511. The wiring pattern 52 includes the plurality of wiring portions 52A to 52P. The plurality of wiring portions 52A to 52P transmit control signals for controlling the control elements 2A and 2B (e.g., the first input signal, the second input signal, the first driving signal, and the second driving signal), and form the paths for transmitting the control signals. The plurality of wiring portions 52A to 52P are formed by, for example, printing a paste containing Ag and then firing it. With this configuration, it is possible to reduce the widths of the paths for transmitting the control signals and increase the density thereof compared with, for example, a configuration in which these transmitting paths are formed using metal lead frames. Accordingly, the semiconductor device A2 can realize a high degree of integration.

In the example shown in the second embodiment, ends at one side of the wires 6J are joined to the control element 2A, and ends on the other side are joined to the pad portions 5211, 521J, and 521K. However, the ends on the other side may be joined to the coupling portions 5231, 523J, and 523K instead of the pad portions 5211, 521J, and 521K, or directly to the control element 2B. As the ends on the other side are connected as appropriate to positions that are closer to the control element 2A in accordance with the shapes of the wiring portions 521, 52J, and 52K, the lengths of the wires 6J can be further reduced. Similarly, in the example shown in the second embodiment, ends at one side of the wires 6K are joined to the control element 2B, and ends on the other side are joined to the pad portions 521E, 521F, and 521G. However, the ends on the other side may be joined to the coupling portions 523E, 523F, and 523G instead of the pad portions 521E, 521F, and 521G, or directly to the control element 2A. As the ends on the other side are connected as appropriate to positions that are closer to the control element 2A in accordance with the shapes of the wiring portions 52E, 52F, and 52G, the lengths of the wires 6K can be further reduced.

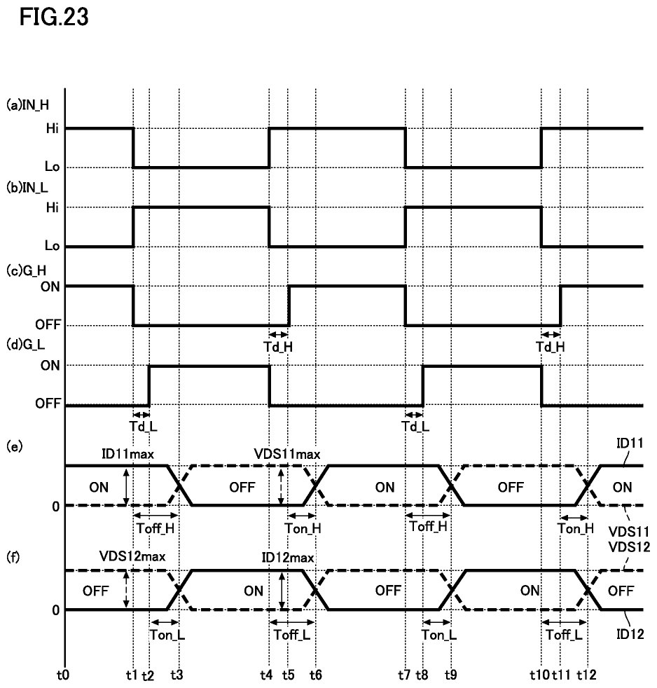

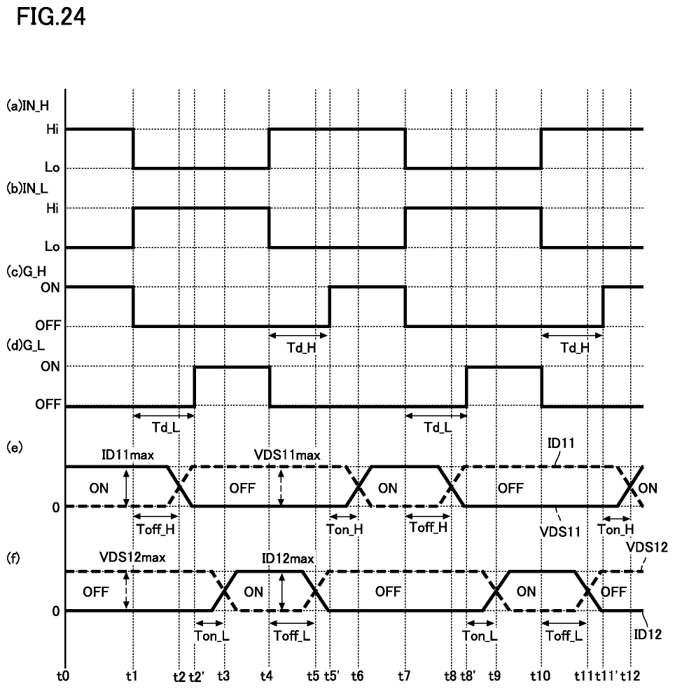

In the examples shown in the first embodiment and the second embodiment, the length of the first period Td_H is the same (or substantially the same) as the length of the off-state transition time Toff_L, which elapses before the semiconductor element 12 is switched to the blocked state, but the first period Td_H may be shorter than the off-state transition time Toff_L or longer than the off-state transition time Toff_L. Similarly, in the examples shown in the first embodiment and the second embodiment, the length of the second period Td_L is the same (or substantially the same) as the length of the off-state transition time Toff_H, which elapses before the semiconductor element 11 is switched to the blocked state, but the second period Td_L may be shorter than the off-state transition time Toff_H or longer than the off-state transition time Toff_H. Semiconductor devices according to such modified examples will be described below with reference to FIGS. 23 and 24.

FIG. 23 is a timing chart showing an operational example of a semiconductor device when the first period Td_H is shorter than the off-state transition time Toff_L, and the second period Td_L is shorter than the off-state transition time Toff_H. In the modified example shown in FIG. 23, the first period Td_H is shortened in consideration of the on-state transition time Ton_H, which elapses when the semiconductor element 11 is switched from the blocked state to the electrical communication state. However, if the sum of the first period Td_H and the on-state transition time Ton_H is shorter than the off-state transition time Toff_L, there may be a period in which the semiconductor element 11 and the semiconductor element 12 are simultaneously in the electrical communication state when the semiconductor element 11 is switched from the blocked state to the electrical communication state. Accordingly, it is necessary to set the first period Td_H such that the sum of the first period Td_H and the on-state transition time Ton_H is longer than the off-state transition time Toff_L. Moreover, the second period Td_L is shortened in consideration of the on-state transition time Ton_L, which elapses when the semiconductor element 12 is switched from the blocked state to the electrical communication state. However, if the sum of the second period Td_L and the on-state transition time Ton_L is shorter than the off-state transition time Toff_H, there may be a period in which the semiconductor element 11 and the semiconductor element 12 are simultaneously in the electrical communication state when the semiconductor element 12 is switched from the blocked state to the electrical communication state. Accordingly, it is necessary to set the second period Td_L such that the sum of the second period Td_L and the on-state transition time Ton_L is longer than the off-state transition time Toff_H.

FIG. 24 is a timing chart showing an operational example of a semiconductor device when the first period Td_H is longer than the off-state transition time Toff_L, and the second period Td_L is longer than the off-state transition time Toff_H. In the modified example shown in FIG. 24, the first period Td_H is longer than the off-state transition time Toff_L, and therefore, the first driving signal G_H is switched from the off signal to the on signal (time points t5′, t11′) after the semiconductor element 12 has been switched from the electrical communication state to the blocked state (time point t5, t11). Accordingly, it is possible to reduce the possibility that the semiconductor element 11 and the semiconductor element 12 are simultaneously in the electrical communication state when the semiconductor element 11 is switched from the electrical communication state to the blocked state. However, as is understood from FIG. 24(e), the period in which the semiconductor element 11 is in the electrical communication state becomes short, and thus the output voltage (AC voltage) may be reduced. Accordingly, it is necessary to set the first period Td_H such that the delay time between when the first input signal IN_H is switched from the low level (off-level) to the high level (on-level) and when the semiconductor element 11 is switched from the blocked state to the electrical communication state is not too long. Moreover, in the modified example shown in FIG. 24, the second period Td_L is longer than the off-state transition time Toff_H, and therefore, the second driving signal G_L is switched from the off signal to the on signal (time points t2′, t8′) after the semiconductor element 11 has been switched from the electrical communication state to the blocked state (time point t2, t8). Accordingly, it is possible to reduce the possibility that the semiconductor element 11 and the semiconductor element 12 are simultaneously in the electrical communication state when the semiconductor element 12 is switched from the electrical communication state to the blocked state. However, as is understood from FIG. 24(f), the period in which the semiconductor element 12 is in the electrical communication state becomes short, and thus the output voltage (AC voltage) may be reduced. Accordingly, it is necessary to set the second period Td_L such that the delay time between when the second input signal IN_L is switched from the low level (off-level) to the high level (on-level) and when the semiconductor element 12 is switched from the blocked state to the electrical communication state is not too long.

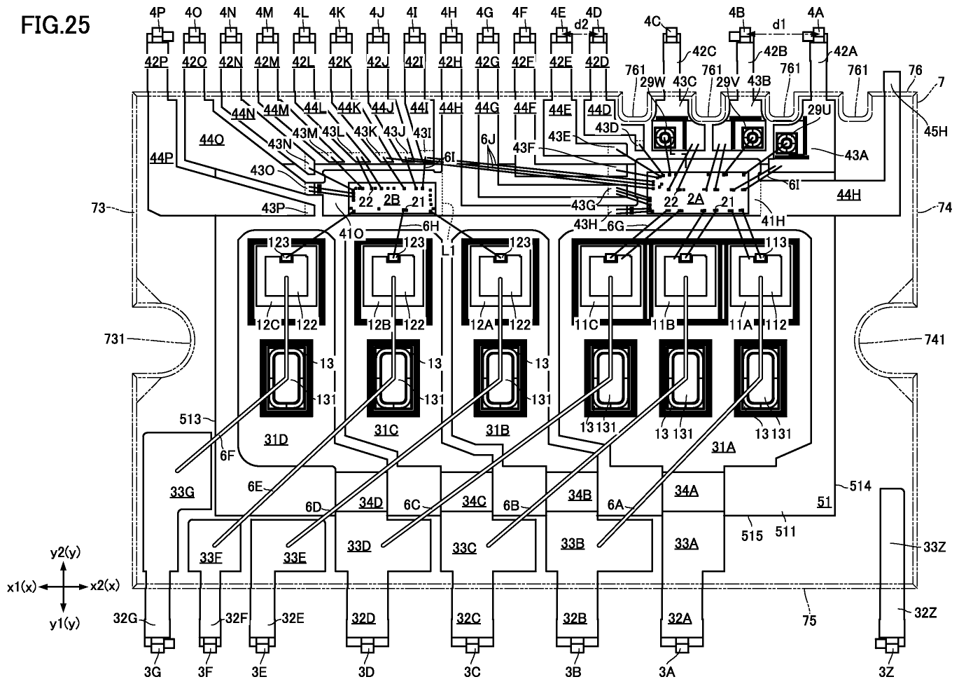

In the examples shown in the first embodiment and the second embodiment, both the first input signal and the second input signal are input to the two control elements 2A and 2B, but it is sufficient that both the first input signal and the second input signal are input to either of the two control elements 2A and 2B. A semiconductor device according to such a modified example will be described below with reference to FIGS. 25 to 27.

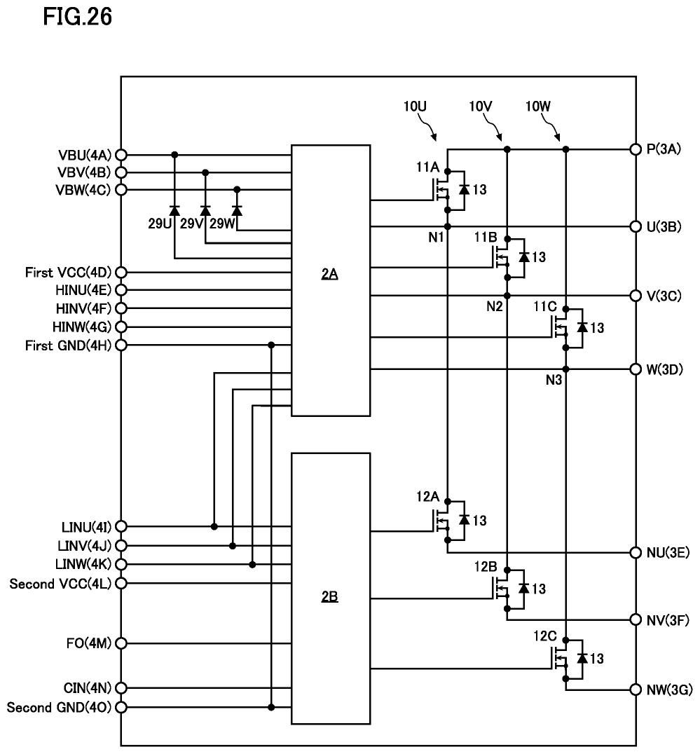

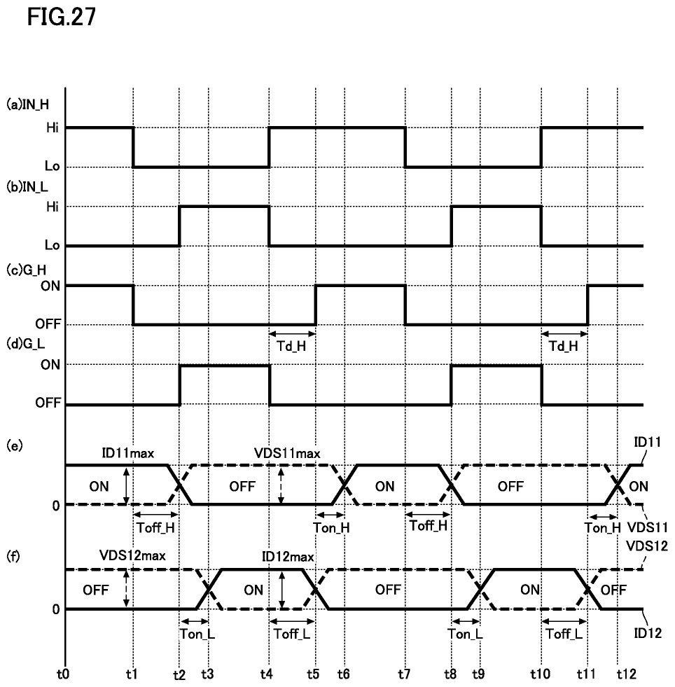

FIG. 25 is a plan view showing a semiconductor device according to this modified example in which the sealing member 7 is indicated by imaginary lines (two-dot dash lines). FIG. 26 shows an example of the circuit configuration of the semiconductor device shown in FIG. 25. FIG. 27 is a timing chart showing an operational example of the semiconductor device shown in FIG. 25. As shown in FIG. 25, the semiconductor device according to this modified example is different from the semiconductor device A1 in that the plurality of wires 6K are not provided. In the examples shown in FIGS. 25 to 27 as well, the first input signal and the second input signal are input to the control element 2A, and therefore, it is possible to suppress an arm short-circuit caused by simultaneous turning-on of the upper and lower arms when the semiconductor element 11 is switched from the blocked state to the electrical communication state. However, as shown in FIG. 26, the first input signal and the second input signal are input to the control element 2A, whereas the first input signal is not input to the control element 2B. Accordingly, the control element 2B cannot determine, based on the first input signal, if the semiconductor element 11 is in the electrical communication state, and thus generates the second driving signal G_L in accordance with the second input signal IN_L that has been input thereto. As a result, in the semiconductor device according to this modified example, the semiconductor element 11 and the semiconductor element 12 may be simultaneously in the electrical communication state when the semiconductor element 12 is switched from the blocked state to the electrical communication state, unlike the semiconductor device A1. Therefore, as shown in FIG. 27, it is sufficient that dead time periods (between time point t1 and time point t2, and between time point t7 to time point t8) in which both the first input signal IN_H and the second input signal IN_L are the low level (off-level) are provided. In the example shown in FIG. 27, the dead time period is provided by reducing the duty ratio of the second input signal IN_L, but the duty ratio of the first input signal IN_H may be reduced, or the duty ratios of the first input signal IN_H and the second input signal IN_L may be reduced.

Although FIGS. 25 to 27 show the examples in which the semiconductor device A1 is not provided with the wires 6K, a configuration may be employed in which the semiconductor device A2 is not provided with the wires 6K. Moreover, although FIGS. 25 to 27 show the examples in which the wires 6K are not provided, a configuration may be employed in which the wires 6J are not provided instead of the wires 6K. In this case, the second input signal is not input to the control element 2A, and only the first input signal is input thereto, whereas the first input signal and the second input signal are input to the control element 2B. Note that, in the modified example in which both the first input signal and the second input signal are input to either the control element 2A or the control element 2B, the fluctuation of the control signal (e.g., first driving signal) in the control element 2A is larger than the fluctuation of the control signal (e.g., second driving signal) in the control element 2B in view of the fact that the control element 2A operates at a higher potential than the control element 2B does. Accordingly, relatively safer switching of the semiconductor element 11 and the semiconductor element 12 can be realized by inputting the first input signal and the second input signal to the control element 2A and thereby delaying the switching of the semiconductor element 11 to the electrical communication state. On the other hand, relatively easily-controllable switching of the semiconductor element 11 and the semiconductor element 12 can be realized by inputting the first input signal and the second input signal to the control element 2B and thereby delaying the switching of the semiconductor element 12 to the electrical communication state. The reason why the control element 2A operates at a higher potential than the control element 2B does is that the reference potential for the second driving signal generated by the control element 2B is the potential of the power GND terminal (the NU terminal (lead 3E), the NV terminal (lead 3F), and the NW terminal (lead 3G)), whereas the reference potential for the first driving signal generated by the control element 2A is the potential of the output terminal (the U terminal (lead 3B), the V terminal (lead 3C), and the W terminal (lead 3D)).

In the first embodiment and the second embodiment, an IPM such as an inverter motor that inputs and outputs a three-phase alternating current is shown as the example, but there is no limitation thereto. The technical idea of the present disclosure can be appropriately applied to a semiconductor device that includes the pair of the semiconductor element 11 and the semiconductor element 12 that are connected to each other in series, and the two control elements 2A and 2B. For example, the semiconductor device according to the present disclosure can be applied to a single-phase inverter circuit that inputs and outputs a single-phase alternating current.

The semiconductor device according to the present disclosure is not limited to the above-described embodiments. Various modifications in design may be made freely in the specific structure of each part of the semiconductor device according to the present disclosure. The present disclosure includes embodiments described in the following clauses.

Clause 1.

A semiconductor device including:

a first semiconductor element configured to receive a first driving signal inputted thereto and to switch between an electrical communication state and a blocked state in accordance with the first driving signal;

a first control element configured to receive a first input signal inputted thereto and to generate a first driving signal based on the first input signal and outputs the first driving signal to the first semiconductor element;

a second semiconductor element configured to receive a second driving signal inputted thereto and to switch between an electrical communication state and a blocked state in accordance with the second driving signal; and

a second control element configured to receive a second input signal inputted thereto and to generate a second driving signal based on the second input signal and outputs the second driving signal to the second semiconductor element,

wherein the first control element is configured to receive the second input signal inputted thereto, and when determining, based on the second input signal, that the second semiconductor element is in the electrical communication state, the first control element delays switching of the first semiconductor element from the blocked state to the electrical communication state.

Clause 2.

The semiconductor device according to Clause 1,

wherein the second input signal is a rectangular pulse wave that has an on-level and an off-level,

the first control element does not switch the first semiconductor element to the electrical communication state until a first period elapses after the second input signal has been switched from the on-level to the off-level, and

the first period is set based on a first transition time that starts when the second driving signal is output from the second control element to the second semiconductor element in order to switch the second semiconductor element from the electrical communication state to the blocked state and terminates when the second semiconductor element is switched from the electrical communication state to the blocked state.

Clause 3.

The semiconductor device according to Clause 2,

wherein the first period is equal to or longer than the first transition time, and

the first semiconductor element is switched from the blocked state to the electrical communication state based on the first driving signal after the first period has elapsed.

Clause 4.

The semiconductor device according to any one of Clauses 1 to 3, further including:

a first lead that includes a first terminal portion for inputting the first input signal; and

a second lead that includes a second terminal portion for inputting the second input signal,

wherein the first lead is in electrical communication with the first control element and the second control element, and

the second lead is in electrical communication with the second control element.

Clause 5.

The semiconductor device according to Clause 4, further including a first connection member connected to the first control element,

wherein the first connection member is in electrical communication with the second lead.

Clause 6.

The semiconductor device according to Clause 5,

wherein the second control element receives the first input signal inputted thereto and when determining, based on the first input signal, that the first semiconductor element is in the electrical communication state, the second control element delays switching of the second semiconductor element from the blocked state to the electrical communication state.

Clause 7.

The semiconductor device according to Clause 6,

wherein the first input signal is a rectangular pulse wave that has an on-level and an off-level,

the second control element does not switch the second semiconductor element to the electrical communication state until a second period elapses after the first input signal has been switched from the on-level to the off-level, and

the second period is set based on a second transition time that starts when the first driving signal is output from the first control element to the first semiconductor element in order to switch the first semiconductor element from the electrical communication state to the blocked state and terminates when the first semiconductor element is switched from the electrical communication state to the blocked state.

Clause 8.

The semiconductor device according to Clause 7,

wherein the second period is equal to or longer than the second transition time, and

the second control element generates the second driving signal in order to switch the second semiconductor element from the blocked state to the electrical communication state after the second period has elapsed.

Clause 9.

The semiconductor device according to Clause 7 or 8,

wherein the second input signal is an inverted signal obtained by inverting the first input signal.

Clause 10.

The semiconductor device according to any one of Clauses 6 to 9, further including a second connection member connected to the second control element,

wherein the second connection member is in electrical communication with the first lead.

Clause 11.

The semiconductor device according to Clause 10, further including:

a substrate having a first surface; and

a wiring pattern made of a conductive material that is formed on the first surface,

wherein the wiring pattern includes a first wiring portion that is in electrical communication with the first lead, and a second wiring portion that is in electrical communication with the second lead,

the first connection member is connected to the second wiring portion, and

the second connection member is connected to the first wiring portion.

Clause 12.

The semiconductor device according to Clause 11,

wherein the wiring pattern includes a third wiring portion to which at least one of the first control element and the second control element is joined.

Clause 13.

The semiconductor device according to Clause 10,

wherein the first lead includes a first conductive portion that is electrically connected to the first terminal portion,

the second lead includes a second conductive portion that is electrically connected to the second terminal portion,

the first connection member is connected to the second conductive portion, and

the second connection member is connected to the first conductive portion.

Clause 14.

The semiconductor device according to Clause 13, further including a third lead to which at least one of the first control element and the second control element is joined.

Clause 15.

The semiconductor device according to any one of Clauses 1 to 14,

wherein the first semiconductor element includes a first electrode, a second electrode, and a third electrode, and the first driving signal is input to the third electrode to switch between a state in which the first electrode and the second electrode are in electrical communication with each other and a state in which these electrodes are blocked from each other, and

the second semiconductor element includes a fourth electrode, a fifth electrode, and a sixth electrode, and the second driving signal is input to the sixth electrode to switch between a state in which the fourth electrode and the fifth electrode are in electrical communication with each other and a state in which these electrodes are blocked from each other.

Clause 16.

The semiconductor device according to Clause 15, further including:

a fourth lead on which the first semiconductor element is mounted and that is in electrical communication with the first electrode;

a fifth lead on which the second semiconductor element is mounted and that is in electrical communication with the fourth electrode and the second electrode; and

a sixth lead that is in electrical communication with the fifth electrode.

Clause 17.

The semiconductor device according to Clause 16,

wherein a DC voltage is applied between the fourth lead and the sixth lead,

the DC voltage is converted to an AC voltage by switching of the first semiconductor element between the electrical communication state and the blocked state and switching of the second semiconductor element between the electrical communication state and the blocked state, and

the AC voltage is applied to the fifth lead.

REFERENCE NUMERALS

| | |
|---|---|
| A1, A2: Semiconductor device | 10U, 10V, 10W: Switching arm |
| 11, 11A, 11B, 11C: Semiconductor | |
| element | |
| 11a: Element obverse surface | |
| 11b: Element reverse surface | 111: First electrode |
| 112: Second electrode | 113: Third electrode |
| 12, 12A, 12B, 12C: Semiconductor | |
| element | |
| 12a: Element obverse surface | 12b: Element reverse surface |
| 121: Fourth electrode | 122: Fifth electrode |
| 123: Sixth electrode | 13: Protection element |
| 131: First electrode | 132: Second electrode |
| 191, 192, 193: Conductive joining | |
| material | |
| 2A, 2B: Control element | 21: First electrode |
| 22: Second electrode | 25: Joining material |
| 29, 29U, 29V, 29W: Electronic | |
| component | |
| 291: Conductive joining material | |
| 3A to 3G, 3Z: Lead | 31A to 31D: Mounting portion |
| 32A to 32G, 32Z: Terminal portion | |
| 33A to 33G, 33Z: Pad portion | 34A to 34D: Coupling portion |
| 39: Joining material | 4A to 4P, 4Z: Lead |
| 41H, 41O: Mounting portion | 42A to 42P: Terminal portion |
| 43A to 43P, 43Z: Pad portion | 44A to 44P: Coupling portion |
| 45H, 45Z: Protruding portion | 46A to 46P: Joining portion |
| 461A to 461P: Through hole | 49: Conductive joining material |
| 51: Support substrate | 511: First surface |
| 512: Second surface | 513: Third surface |
| 514: Fourth surface | 515: Fifth surface |
| 516: Sixth surface | 52: Wiring pattern |
| 52A to 52P: Wiring portion | 521A to 521P: Pad portion |
| 522A to 522P: Pad portion | 523A to 523P: Coupling portion |
| 524H, 524O: Mounting portion | 53A to 53D: Joining portion |
| 6: Connection member | 6A to 6K: Wire |
| 7: Sealing member | 71: Resin obverse surface |
| 72: Resin reverse surface | 73 to 76: Resin side surface |
| 731, 741, 761: Recessed portion | |

1. A semiconductor device comprising:
a first semiconductor element configured to receive a first driving signal inputted thereto and to switch between an electrical communication state and a blocked state in accordance with the first driving signal;
a first control element configured to receive a first input signal inputted thereto and to generate a first driving signal based on the first input signal and outputs the first driving signal to the first semiconductor element;
a second semiconductor element configured to receive a second driving signal inputted thereto and to switch between an electrical communication state and a blocked state in accordance with the second driving signal; and
a second control element configured to receive a second input signal inputted thereto and to generate a second driving signal based on the second input signal and outputs the second driving signal to the second semiconductor element,
wherein the first control element is configured to receive the second input signal inputted thereto, and when determining, based on the second input signal, that the second semiconductor element is in the electrical communication state, the first control element delays switching of the first semiconductor element from the blocked state to the electrical communication state.

2. The semiconductor device according to claim 1,
wherein the second input signal is a rectangular pulse wave that has an on-level and an off-level,
the first control element does not switch the first semiconductor element to the electrical communication state until a first period elapses after the second input signal has been switched from the on-level to the off-level, and
the first period is set based on a first transition time that starts when the second driving signal is output from the second control element to the second semiconductor element in order to switch the second semiconductor element from the electrical communication state to the blocked state and terminates when the second semiconductor element is switched from the electrical communication state to the blocked state.

3. The semiconductor device according to claim 2,
wherein the first period is equal to or longer than the first transition time, and
the first semiconductor element is switched from the blocked state to the electrical communication state based on the first driving signal after the first period has elapsed.

4. The semiconductor device according to claim 1, further including:
a first lead that includes a first terminal portion for inputting the first input signal; and
a second lead that includes a second terminal portion for inputting the second input signal,
wherein the first lead is in electrical communication with the first control element and the second control element, and
the second lead is in electrical communication with the second control element.

5. The semiconductor device according to claim 4, further including a first connection member connected to the first control element,
wherein the first connection member is in electrical communication with the second lead.

6. The semiconductor device according to claim 5,
wherein the second control element receives the first input signal inputted thereto and when determining, based on the first input signal, that the first semiconductor element is in the electrical communication state, the second control element delays switching of the second semiconductor element from the blocked state to the electrical communication state.

7. The semiconductor device according to claim 6,
wherein the first input signal is a rectangular pulse wave that has an on-level and an off-level,
the second control element does not switch the second semiconductor element to the electrical communication state until a second period elapses after the first input signal has been switched from the on-level to the off-level, and
the second period is set based on a second transition time that starts when the first driving signal is output from the first control element to the first semiconductor element in order to switch the first semiconductor element from the electrical communication state to the blocked state and terminates when the first semiconductor element is switched from the electrical communication state to the blocked state.

8. The semiconductor device according to claim 7,
wherein the second period is equal to or longer than the second transition time, and
the second control element generates the second driving signal in order to switch the second semiconductor element from the blocked state to the electrical communication state after the second period has elapsed.

9. The semiconductor device according to claim 7,
wherein the second input signal is an inverted signal obtained by inverting the first input signal.

10. The semiconductor device according to claim 6, further including a second connection member connected to the second control element,
wherein the second connection member is in electrical communication with the first lead.

11. The semiconductor device according to claim 10, further including:
a substrate having a first surface; and
a wiring pattern made of a conductive material that is formed on the first surface,
wherein the wiring pattern includes a first wiring portion that is in electrical communication with the first lead, and a second wiring portion that is in electrical communication with the second lead,
the first connection member is connected to the second wiring portion, and
the second connection member is connected to the first wiring portion.

12. The semiconductor device according to claim 11,
wherein the wiring pattern includes a third wiring portion to which at least one of the first control element and the second control element is joined.

13. The semiconductor device according to claim 10,
wherein the first lead includes a first conductive portion that is electrically connected to the first terminal portion,
the second lead includes a second conductive portion that is electrically connected to the second terminal portion,
the first connection member is connected to the second conductive portion, and
the second connection member is connected to the first conductive portion.

14. The semiconductor device according to claim 13, further including a third lead to which at least one of the first control element and the second control element is joined.

15. The semiconductor device according to claim 1,
wherein the first semiconductor element includes a first electrode, a second electrode, and a third electrode, and the first driving signal is input to the third electrode to switch between a state in which the first electrode and the second electrode are in electrical communication with each other and a state in which these electrodes are blocked from each other, and
the second semiconductor element includes a fourth electrode, a fifth electrode, and a sixth electrode, and the second driving signal is input to the sixth electrode to switch between a state in which the fourth electrode and the fifth electrode are in electrical communication with each other and a state in which these electrodes are blocked from each other.

16. The semiconductor device according to claim 15, further including:
a fourth lead on which the first semiconductor element is mounted and that is in electrical communication with the first electrode;
a fifth lead on which the second semiconductor element is mounted and that is in electrical communication with the fourth electrode and the second electrode; and
a sixth lead that is in electrical communication with the fifth electrode.

17. The semiconductor device according to claim 16,
wherein a DC voltage is applied between the fourth lead and the sixth lead,
the DC voltage is converted to an AC voltage by switching of the first semiconductor element between the electrical communication state and the blocked state and switching of the second semiconductor element between the electrical communication state and the blocked state, and
the AC voltage is applied to the fifth lead.
